(19) United States
(12) Patent Application Publication
(10) Pub. No.: US 2025/0364996 A1
(43) Pub. Date: Nov. 27, 2025

(54) INTEGRATED CIRCUIT DEVICE AND METHOD

(71) Applicant: TAIWAN SEMICONDUCTOR MANUFACTURING COMPANY, LTD., Hsinchu (TW)

(72) Inventor: Shenggao LI, Hsinchu (TW)

(21) Appl. No.: 19/292,331

(22) Filed: Aug. 6, 2025

Related U.S. Application Data
(63) Continuation of application No. 18/772,677, filed on Jul. 15, 2024.
(60) Provisional application No. 63/570,446, filed on Mar. 27, 2024.

(51) Int. Cl. H03L 7/08; H03K 3/037; H03K 5/00; H03K 5/01

(52) U.S. Cl. CPC H03L 7/08; H03K 3/037; H03K 5/01; H03K 2005/00013

(57) ABSTRACT

An integrated circuit (IC) device includes a first die including a first transmitting circuit, a first receiving circuit, and a first circuit. The first transmitting circuit transmits an output clock signal corresponding to a first clock signal. The first receiving circuit receives an input clock signal and an input signal, and outputs, based on the input clock signal, a first signal corresponding to the input signal. The first circuit outputs, based on the first clock signal, a second signal corresponding to the first signal. The first circuit, in response to a first value of a first selection signal, outputs the second signal in response to a first edge of the first clock signal. The first circuit, in response to a second value different from the first value of the first selection signal, outputs the second signal in response to a second edge of the first clock signal.

### RELATED APPLICATION(S)

This application is a continuation application of U.S. patent application Ser. No. 18/772,677, filed Jul. 15, 2024, which claims the benefit of U.S. Provisional Application No. 63/570,446, filed Mar. 27, 2024. The above-referenced applications are herein incorporated by reference in their entireties.

### BACKGROUND

Integrated circuit (IC) devices have grown in complexity, and often operate at increased clock frequencies with lowered power consumption and/or voltage. Providing accurate clock signals in such IC devices is a design concern. Clock accuracy is a consideration especially in three dimensional (3D) IC devices having multiple chips (or dies) stacked on and bonded to each other, and/or stacked on and bonded to a substrate, interposer, wafer, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic circuit diagram of an IC device, in accordance with some embodiments.

FIG. 1B is a schematic timing diagram showing various signals in operations of the IC device of FIG. 1A, in accordance with some embodiments.

FIG. 2 is a schematic circuit diagram of a clock management circuit, in accordance with some embodiments.

FIG. 3 is a schematic circuit diagram of an IC device, in accordance with some embodiments.

FIG. 4A is a schematic circuit diagram of an IC device, in accordance with some embodiments.

FIG. 4B is a schematic timing diagram showing various signals in operations of the IC device of FIG. 4A, in accordance with some embodiments.

FIGS. 4C-4D are schematic circuit diagrams of various IC devices, in accordance with some embodiments.

FIGS. 5A-5B are schematic circuit diagrams of various IC devices, in accordance with some embodiments.

FIGS. 6A-6C are flowcharts of various methods, in accordance with some embodiments.

FIG. 7 is a schematic diagram of a clock distribution system for an IC device, in accordance with some embodiments.

FIGS. 8A-8B are schematic diagrams of various IC devices, in accordance with some embodiments.

FIG. 9 is a block diagram of an electronic design automation (EDA) system in accordance with some embodiments.

FIG. 10 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a first semiconductor die is coupled to a second semiconductor die. Each of the first semiconductor die and second semiconductor die comprises a transmitting circuit (or output circuit), and a receiving circuit (or input circuit) correspondingly coupled to the receiving circuit and transmitting circuit of the other semiconductor die. In at least one embodiment, the second semiconductor die returns a clock signal received from the first semiconductor die back to the first semiconductor die, and also uses the returned clock signal to send data to the first semiconductor die. In some embodiments, a circuit, such as a flip-flop, is coupled to the receiving circuit of the first semiconductor die, and configured to output the data received from the second semiconductor die in response to an active clock edge of a clock signal of the first semiconductor die. The active clock edge is selectable between a rising edge or a falling edge to ensure that the correct data are output. In at least one embodiment, it is possible to achieve one or more effects including, but not limited to, data accuracy, extra timing margin for clock in die-to-die interconnections for maximum robustness and minimum latency in interface (I/F) timing, a robust input/output (I/O) interface without using a first-in-first-out (FIFO) circuit thereby saving power and area, sufficient setup time and/or hold time without being affected by duty cycle errors and/or jitter, or the like.

In some embodiments, the second semiconductor die comprises a phase-locked loop (PLL) coupled to the receiving circuit thereof. The PLL is configured to, based on the clock signal provided from the first semiconductor die, generate a clock signal to be used by the second semiconductor die to send data to the first semiconductor die. In at least one embodiment, the PLL comprises, in a feedback path thereof, at least one delay circuit configured to match and compensate for delays over communication channels between the first semiconductor die and second semiconductor die. In at least one embodiment, where such a PLL is included in the second semiconductor die, the described flip-flop is omitted from the first semiconductor die. In at least one embodiment, a clock signal used by the second semiconductor die to send data to the first semiconductor die is selectable between the clock signal provided from the first semiconductor die and the clock signal generated by the PLL. As a result, it is possible in one or more embodiments to achieve one or more effects including, but not limited to, improved timing margins, valuable Si-testing despite an additional power and/or area penalty on the second semiconductor die, or the like. Further advantages and/or effects are achievable in one or more embodiments as described herein.

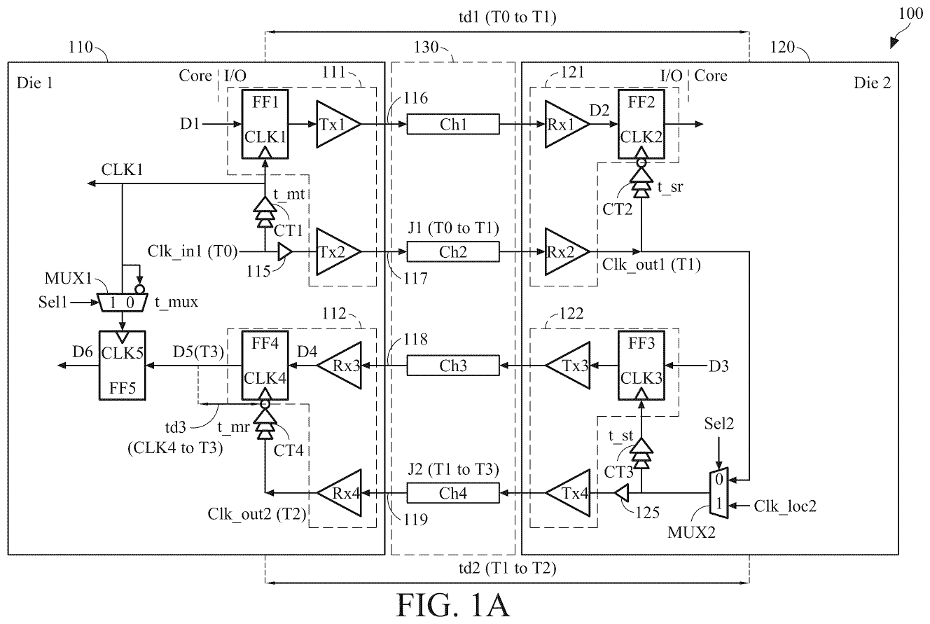

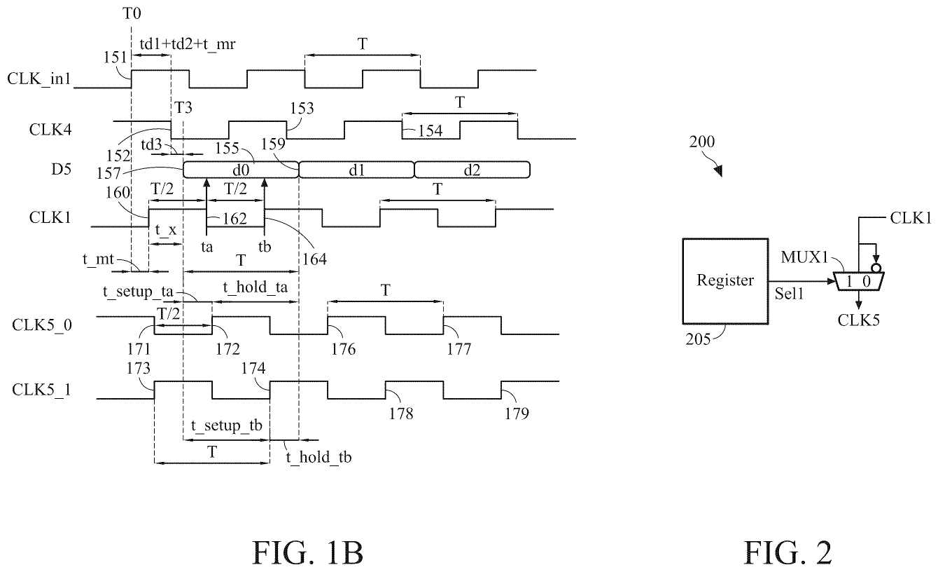

FIG. 1A is a schematic circuit diagram of an IC device 100, in accordance with some embodiments.

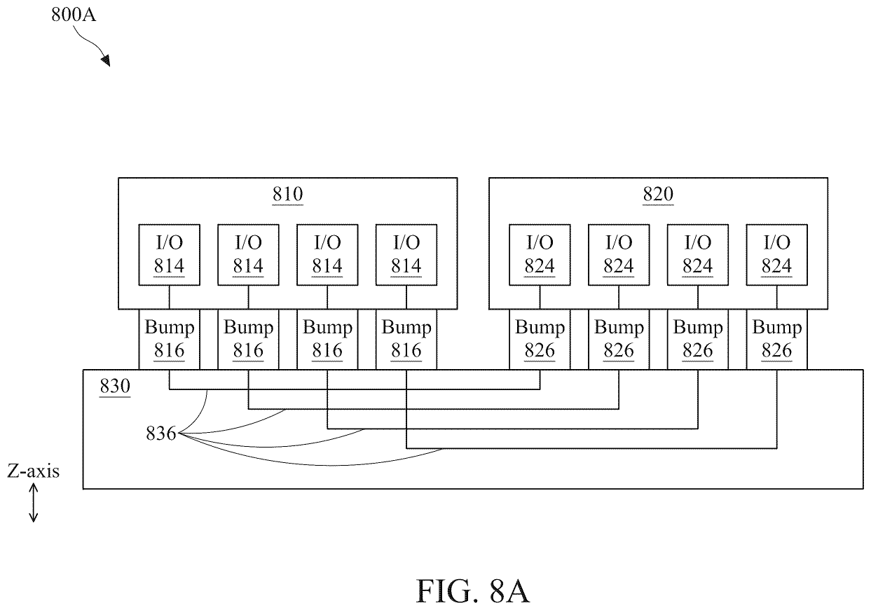

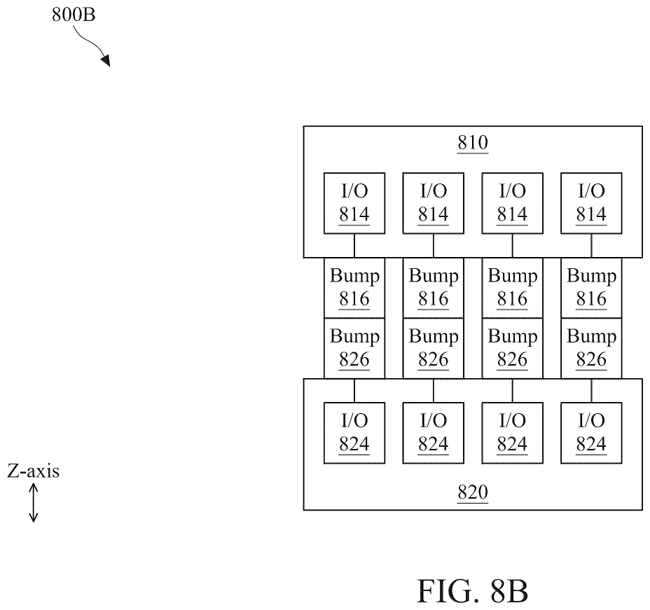

The IC device 100 comprises a first semiconductor die 110 (labelled in the drawing as “Die 1”) and a second semiconductor die 120 (labelled in the drawing as “Die 2”) electrically and/or physically coupled to each other by a plurality of die-to-die (D2D) interface structures 130. In some embodiments, the semiconductor die 110 and the semiconductor die 120 are stacked over each other, and are physically bonded and electrically coupled to each other in a three-dimensional (3D) IC arrangement. In some embodiments, the semiconductor die 110 and the semiconductor die 120 are arranged side-by-side on, and physically bonded to, a further substrate, wafer, interposer, or die (not shown), and are electrically coupled to each other through the further substrate, wafer, interposer, die, or the like, in a further 3D IC arrangement. Examples of 3D IC arrangements include, but are not limited to, CoWoS (Chip-on-Wafer-on-Substrate), InFO (Integrated Fan-Out) wafer level packaging, SoIC (System on Integrated Chips), or the like. In some embodiments, the IC device 100 comprises more than two semiconductor dies electrically and/or physically coupled to each other. In some embodiments, the IC device 100 has one die, such as the semiconductor die 110 or the semiconductor die 120, whereas the other die is omitted, for example, before multiple dies are bonded together in an 3D IC arrangement. Non-limiting examples of various 3D IC arrangements are described with respect to FIGS. 8A-8B. Examples of the D2D interface structures 130 include, but are not limited to, through-silicon vias (TSVs), hybrid bumps, ubumps (micro bumps), or the like.

Each of the semiconductor dies 110, 120 comprises one or more functional circuits and one or more input/output (I/O) circuits electrically coupled to the one or more functional circuits. In at least one embodiment, each of the semiconductor dies 110, 120 comprises a plurality of I/O circuits electrically coupled to each functional circuit. In FIG. 1A, functional circuits and I/O circuits are designated by corresponding labels “Core” and “I/O”, and schematically differentiated from each other by a dot-dot line between the labels “Core” and “I/O.” Specifically, as illustrated in FIG. 1A, the semiconductor die 110 comprises I/O circuits on the right side of the corresponding dot-dot line, and at least one functional circuit on the left side of the corresponding dot-dot line. Similarly, as illustrated in FIG. 1A, the semiconductor die 120 comprises I/O circuits on the left side of the corresponding dot-dot line, and at least one functional circuit on the right side of the corresponding dot-dot line. The illustrated differentiation between functional circuits and I/O circuits is an example. Other arrangements are within the scopes of various embodiments.

A functional circuit of a semiconductor die is configured to perform an intended function, e.g., data processing or data storage, of the semiconductor die. Examples of one or more circuits, logics, or cells included in the functional circuit include, but are not limited to, AND, OR, NAND, NOR, XOR, INV, OR-AND-Invert (OAI), MUX, Flip-flop, BUFF, Latch, delay, clock, memory, or the like. The circuits, logics, or cells included in the functional circuit include functional transistors or core transistors. Examples of transistors in the functional circuit, as well as in the other circuits (such as the I/O circuits) described herein, include, but are not limited to, metal oxide semiconductor field effect transistors (MOSFETs), complementary metal oxide semiconductor (CMOS) transistors, P-channel metal-oxide semiconductor (PMOS) transistors, N-channel metal-oxide semiconductor (NMOS) transistors, bipolar junction transistors (BJTs), high voltage transistors, high frequency transistors, P-channel and/or N-channel field effect transistors (PFETs/NFETs), FinFETs, planar MOS transistors with raised source/drains, nanosheet FETs, nanowire FETs, or the like.

An I/O circuit is electrically coupled to a functional circuit on a same semiconductor die, and is configured as an interface circuit between the functional circuit and external circuitry outside the semiconductor die. In the example configuration in FIG. 1A, representative I/O circuits of the semiconductor die 110 comprise a first transmitting circuit 111 and a first receiving circuit 112, whereas representative I/O circuits of the semiconductor die 120 comprise a second receiving circuit 121 and a second transmitting circuit 122.

The transmitting circuit 111 of the semiconductor die 110 comprises a flip-flop FF1, a data output buffer Tx1, and a clock output buffer Tx2. The flip-flop FF1 comprises an input configured to receive a signal D1 from the functional circuit of the semiconductor die 110, a clock input configured to receive a clock signal CLK1, and an output. For simplicity, a conductive structure, e.g., a node, an input, an output, or the like, and the signal thereof are designated by the same reference numeral or label. For example, both the clock input of the flip-flop FF1 and the clock signal supplied thereto are designated by the same label “CLK1”. The data output buffer Tx1 comprises an input coupled to the output of the flip-flop FF1, and an output coupled to a corresponding D2D interface structure referred to herein as a channel Ch1. The clock output buffer Tx2 comprises an input configured to receive a clock signal Clk_in1 through a clock driver (or clock buffer) 115, and an output coupled to a corresponding D2D interface structure referred to herein as a channel Ch2. In at least one embodiment, the clock driver 115 is omitted. The semiconductor die 110 further comprises a clock tree CT1 configured to propagate the clock signal Clk_in1 to other circuits. For example, the clock signal CLK1 corresponds to the clock signal Clk_in1 propagated through the clock tree CT1 and arriving at the clock input of the flip-flop FF1.

The receiving circuit 121 of the semiconductor die 120 is coupled to the transmitting circuit 111 of the semiconductor die 110 through the channel Ch1 and channel Ch2. The receiving circuit 121 comprises a flip-flop FF2, a data input buffer Rx1, and a clock input buffer Rx2. The data input buffer Rx1 comprises an input coupled to the output of the data output buffer Tx1 through the channel Ch1, and an output. The flip-flop FF2 comprises an input coupled to the output of the data input buffer Rx1 to receive a signal D2, a clock input configured to receive a clock signal CLK2, and an output. The signal D2 corresponds to the signal D1 transmitted by the transmitting circuit 111 through the channel Ch1, received and provided by the data input buffer Rx1. The output of the flip-flop FF2 is configured to provide the signal D2 to the functional circuit of the semiconductor die 120. The clock input buffer Rx2 comprises an input coupled to the output of the clock output buffer Tx2 through the channel Ch2, and an output configured to output a clock signal Clk_out1. The clock signal Clk_out1 corresponds to the clock signal Clk_in1 passed through the clock driver 115, transmitted by the clock output buffer Tx2 through the channel Ch2, received and provided by the clock input buffer Rx2. The semiconductor die 120 further comprises a clock tree CT2 configured to propagate the clock signal Clk_out1 to other circuits. For example, the clock signal CLK2 corresponds to the clock signal Clk_out1 propagated through the clock tree CT2 and arriving at the clock input of the flip-flop FF2. In the example configuration in FIG. 1A, the clock signal CLK2 is an inverted clock signal, i.e., a high level of clock signal CLK2 corresponds to a low level of clock signal Clk_out1, and vice versa.

In the example configuration in FIG. 1A, the semiconductor die 120 further comprises a multiplexer MUX2. The multiplexer MUX2 comprises a first input, a second input, a selection input, and an output. The first input (with label “0” in FIG. 1A) is coupled to the output of the clock input buffer Rx2 to receive the clock signal Clk_out1. The second input (with label “1” in FIG. 1A) configured to receive a clock signal Clk_loc2 of the semiconductor die 120. The selection input is configured to receive, e.g., from a control circuit in the functional circuit of the semiconductor die 120, a selection signal Sel2. The output of the multiplexer MUX2 is coupled to the transmitting circuit 122. Depending on a value of the selection signal Sel2, the multiplexer MUX2 is configured to output a clock signal Clk_in2 corresponding to either the clock signal Clk_out1 or the clock signal Clk_loc2. For example, in response to the selection signal Sel2 having a value of logic “0”, the multiplexer MUX2 is configured to output the clock signal Clk_in2 corresponding to the clock signal Clk_out1, and in response to the selection signal Sel2 having a value of logic “1”, the multiplexer MUX2 is configured to output the clock signal Clk_in2 corresponding to the clock signal Clk_loc2.

In some embodiments, the clock signal Clk_in1 corresponds to a master clock signal provided from the semiconductor die 110 to the semiconductor die 120, whereas the clock signal Clk_loc2 corresponds to a local clock signal of the semiconductor die 120. In at least one embodiment, the clock signal Clk_loc2 is independent from the clock signal Clk_in1 and variants thereof (e.g., clock signal CLK1, clock signal CLK2, clock signal Clk_out1, or the like). For example, the clock signal Clk_loc2 and the clock signal Clk_in1 have different clock sources. The clock signal Clk_loc2 is an example of a second clock signal. In at least one embodiment, the multiplexer MUX2 permits a selection, e.g., by the control circuit in the functional circuit of the semiconductor die 120, to use either the master clock signal provided from the semiconductor die 110 or the local clock signal of the semiconductor die 120 to send data to the semiconductor die 110. The former makes it possible in one or more embodiments to achieve one or more effects described herein, such as extra timing margin, clock robustness, or the like. The latter is helpful in situations or applications where it is desirable for two coupled semiconductor dies to communicate with each other using their own, independent clocks.

In the following description, unless otherwise specified, the multiplexer MUX2 outputs the clock signal Clk_in2 corresponding to the clock signal Clk_out1, i.e., the clock signal received from the semiconductor die 110 is returned back to the semiconductor die 110 and is used for transmitting data from the semiconductor die 120 to the semiconductor die 110. In this configuration, the clock signal Clk_in2 is sometimes referred to as the returned clock signal. In at least one embodiment, the multiplexer MUX2 is omitted, and the output of the clock input buffer Rx2 is coupled to the transmitting circuit 122 in an arrangement corresponding to the clock signal Clk_out1 being the clock signal Clk_in2.

The transmitting circuit 122 of the semiconductor die 120 comprises a flip-flop FF3, a data output buffer Tx3, and a clock output buffer Tx4. The flip-flop FF3 comprises an input configured to receive a signal D3 from the functional circuit of the semiconductor die 120, a clock input configured to receive a clock signal CLK3, and an output. The data output buffer Tx3 comprises an input coupled to the output of the flip-flop FF3, and an output coupled to a corresponding D2D interface structure referred to herein as a channel Ch3. The clock output buffer Tx4 comprises an input configured to receive the clock signal Clk_in2 through the clock driver 125, and an output coupled to a corresponding D2D interface structure referred to herein as a channel Ch4. In at least one embodiment, the clock driver 125 is omitted. The semiconductor die 120 further comprises a clock tree CT3 configured to propagate the clock signal Clk_in2 to other circuits. For example, the clock signal CLK3 corresponds to the clock signal Clk_in2 propagated through the clock tree CT3 and arriving at the clock input of the flip-flop FF3.

The receiving circuit 112 of the semiconductor die 110 is coupled to the transmitting circuit 122 of the semiconductor die 120 through the channel Ch3 and channel Ch4. The receiving circuit 112 comprises a flip-flop FF4, a data input buffer Rx3, and a clock input buffer Rx4. The data input buffer Rx3 comprises an input coupled to the output of the data output buffer Tx3 through the channel Ch3, and an output configured to output a signal D4. The signal D4 corresponds to the signal D3 transmitted by the transmitting circuit 122 through the channel Ch3, received and provided by the data input buffer Rx3. The flip-flop FF4 comprises an input coupled to the output of the data input buffer Rx3 to receive the signal D4, a clock input configured to receive a clock signal CLK4, and an output configured to provide a signal D5 corresponding to the signal D4. The clock input buffer Rx4 comprises an input coupled to the output of the clock output buffer Tx4 through the channel Ch4, and an output configured to output a clock signal Clk_out2. The clock signal Clk_out2 corresponds to the clock signal Clk_in2 passed through the clock driver 125, transmitted by the clock output buffer Tx4 through the channel Ch4, received and provided by the clock input buffer Rx4. The semiconductor die 110 further comprises a clock tree CT4 configured to propagate the clock signal Clk_out2 to other circuits. For example, the clock signal CLK4 corresponds to the clock signal Clk_out2 propagated through the clock tree CT4 and arriving at the clock input of the flip-flop FF4. In the example configuration in FIG. 1A, the clock signal CLK4 is an inverted clock signal, i.e., a high level of clock signal CLK4 corresponds to a low level of clock signal Clk_out2, and vice versa.

In the example configuration in FIG. 1A, the semiconductor die 110 further comprises a multiplexer MUX1 and a flip-flop FF5. The multiplexer MUX1 comprises a first input, a second input, a selection input, and an output. The first input (with label “0” in FIG. 1A) is an inverting input configured to receive the clock signal CLK1, and the second input (with label “1” in FIG. 1A) is a non-inverting input configured to receive the clock signal CLK1. In other words, the clock signal CLK1 and an inverted clock signal of the clock signal CLK1 (herein referred to as “inverted clock signal CLK1”) are inputted to the multiplexer MUX1. The selection input is configured to receive, e.g., from a control circuit in the functional circuit of the semiconductor die 110, a selection signal Sel1. The output of the multiplexer MUX1 is coupled to the clock input of the flip-flop FF5. Depending on a value of the selection signal Sel1, the multiplexer MUX1 is configured to output a clock signal CLK5 corresponding to either the clock signal CLK1 or the inverted clock signal CLK1. For example, in response to the selection signal Sel1 having a value of logic “0”, the multiplexer MUX1 is configured to output the clock signal CLK5 corresponding to the inverted clock signal CLK1, and in response to the selection signal Sel1 having a value of logic “1”, the multiplexer MUX1 is configured to output the clock signal CLK5 corresponding to the clock signal CLK1. Logic “1” is an example of one of a first value and a second value of the selection signal Sel1, and logic “0” is an example of the other of the first value and second value of the selection signal Sel1. The flip-flop FF5 comprises an input coupled to the output of the flip-flop FF4 to receive the signal D5, a clock input coupled to the output of the multiplexer MUX1 to receive the clock signal CLK5, and an output configured to provide a signal D6 corresponding to the signal D5 to the functional circuit of the semiconductor die 110. In some embodiments, the multiplexer MUX1 and/or flip-flop FF5 is/are omitted.

A flip-flop is configured to output a signal or data received at an input of the flip-flop, based on a clock signal at a clock input of the flip-flop. For example, the flip-flop FF1 outputs the signal D1 received at the input of the flip-flop FF1, in response to an edge (also referred to herein as “active clock edge”) of the clock signal CLK1 at the clock input of the flip-flop FF1. For simplicity, the active clock edges of all flip-flops described herein are rising edges. For example, the flip-flop FF1 outputs the signal D1 in response to a rising edge of the clock signal CLK1. For another example, the flip-flop FF2 outputs the signal D2 in response to a rising edge of the clock signal CLK2. However, because the clock signal CLK2 is an inverted clock signal, the flip-flop FF2 outputs the signal D2 in response to (with some time delay associated with the clock tree CT2) a falling edge of the clock signal Clk_out1. In some embodiments, at least one of the flip-flops described herein has a falling edge as the active clock edge. The described flip-flops are examples. Other circuits configured to output, based on a clock signal, a signal or data received at an input thereof are within the scopes of various embodiments.

The described multiplexer MUX1 or multiplexer MUX2 is an example. Other selection circuits configured to permit a selection of a signal (e.g., a clock signal) among two or more signals (e.g., clock signals) are within the scopes of various embodiments. The described logic “0” and logic “1” are examples. Other configurations in which the described logic “0” is replaced with logic “1”, and vice versa, are within the scopes of various embodiments. Examples of one or more circuits in at least one of the described input buffers and/or output buffers include, but are not limited to, buffers, latches, level shifters, inverters, or the like. In some embodiments, for the semiconductor die 110, the data output buffer Tx1 and data input buffer Rx3 configure a data I/O circuit, whereas the clock output buffer Tx2 and clock input buffer Rx4 configure a clock I/O circuit. In some embodiments, for the semiconductor die 120, the data output buffer Tx3 and data input buffer Rx1 configure a data I/O circuit, whereas the clock output buffer Tx4 and clock input buffer Rx2 configure a clock I/O circuit. The multiplexer MUX1, multiplexer MUX2 are examples of a clock management circuit, or at least a part thereof, in accordance with some embodiments.

As seen from the semiconductor die 110, the transmitting circuit 111 is configured to transmit an output signal 116 and an output clock signal 117 to the receiving circuit 121 correspondingly over the channel Ch1 and channel Ch2, and the receiving circuit 112 is configured to receive an input signal 118 and an input clock signal 119 from the transmitting circuit 122 correspondingly over the channel Ch3 and channel Ch4.

Specifically, the transmitting circuit 111 is configured to transmit the output signal 116, based on the clock signal CLK1 at the clock input of the flip-flop FF1. The output signal 116 corresponds to the signal D1 input into the flip-flop FF1. The clock signal CLK1 is an example of a first clock signal. The receiving circuit 121 is configured to receive the output signal 116 from the transmitting circuit 111, and provide the received output signal 116 from the data input buffer Rx1 as the signal D2.

The transmitting circuit 111 is further configured to transmit the output clock signal 117 which comprises the clock signal Clk_in1 passing through the clock driver 115 and clock output buffer Tx2, and corresponds to the clock signal CLK1. The receiving circuit 121 is configured to receive the output clock signal 117 from the transmitting circuit 111, and provide the received output clock signal 117 from the output of the clock input buffer Rx2 as the clock signal Clk_out1. In response to the selection signal Sel1 being logic “0”, the clock signal Clk_out1 is supplied by the multiplexer MUX2 as the clock signal Clk_in2 to the transmitting circuit 122 through the clock driver 125 and clock tree CT3.

The transmitting circuit 122 is configured to transmit the input signal 118 to the receiving circuit 112, based on the clock signal CLK3 which is the clock signal Clk_in2 propagated through the clock tree CT3 to the clock input of the flip-flop FF3. The input signal 118 corresponds to the signal D3 input into the flip-flop FF3. In some embodiments, the signal D3 is responsive to the signal D1, for example, when the semiconductor die 110 and semiconductor die 120 cooperate in a same application, or in a calibration process described herein. In at least one embodiment, the signal D3 is independent from the signal D1. The transmitting circuit 122 is configured to transmit the input clock signal 119 to the receiving circuit 112. The input clock signal 119 corresponds to the clock signal Clk_in2 passing through the clock driver 125 and clock output buffer Tx4.

The receiving circuit 112 is configured to receive the input signal 118 and input clock signal 119, and provide the received input signal 118 and input clock signal 119 correspondingly as the signal D4 at the output of the data input buffer Rx3 and the clock signal Clk_out2 at the output of the clock input buffer Rx4. The receiving circuit 112 is further configured to output the signal D5, based on the clock signal CLK4 which is the clock signal Clk_out2 propagated through the clock tree CT4 to the clock input of the flip-flop FF4. The signal D5 is an example of a first signal.

The flip-flop FF5 is configured to provide the signal D6 corresponding to the signal D5, based on a clock signal CLK5 at the clock input of the flip-flop FF5. The clock signal CLK5 is provided by the multiplexer MUX1 based on the selection signal Sel1, and corresponds to the clock signal CLK1. The flip-flop FF5 and multiplexer MUX1 constitute an example of a first circuit configured to output, based on the first clock signal (i.e., clock signal CLK1), a second signal (i.e., signal D6) corresponding to the first signal (i.e., signal D5).

As described herein, various signals in the IC device 100 are provided based on corresponding clock signals. Therefore, clock accuracy is a consideration to ensure correct operations of the IC device 100 as designed and/or intended. During the clock signal transmissions between the semiconductor die 110 and semiconductor die 120, numerous time delays and/or jitters are presented and potentially affect clock accuracy and/or latency. A time delay is generally a constant or predictable parameter corresponding to an increase in the time it takes for a signal, e.g., a clock signal, to travel along a signal path from one point to another. Jitter, on the other hand, manifests as fluctuations of time delays. Example types of jitter include deterministic jitter (Dj) and random jitter (Rj). Dj is a type of jitter that is predictable. Rj, on the other hand, is unpredictable.

A time delay of a circuit element, or a signal path, depends on various physical and/or electrical characteristics of the circuit element, or various circuit elements along the signal path. As illustrated in FIG. 1A and FIG. 1B, the clock signal Clk_in1 has a clock edge, e.g., a rising edge, at a timing T0. The clock signal Clk_in1 passes through a first signal path including the clock driver 115, clock output buffer Tx2, channel Ch2, clock input buffer Rx2, and arrives at the semiconductor die 120 as the clock signal Clk_out1. The clock edge having the timing T0 of the clock signal Clk_in1 becomes, or corresponds to, a clock edge having a timing T1 of the clock signal Clk_out1. A difference between the timing T1 and timing T0 is a time delay td1 of the described first signal path, as schematically indicated in FIG. 1A. Jitter J1 along the first signal path between timing T0 and timing T1 generally occurs over the channel Ch2, as also schematically indicated in FIG. 1A.

The clock signal Clk_out1 passes through a second signal path including the multiplexer MUX2, clock driver 125, clock output buffer Tx4, clock input buffer Rx4, and arrives at the semiconductor die 110 as the clock signal Clk_out2. The clock edge having the timing T1 of the clock signal Clk_out1 becomes, or corresponds to, a clock edge having a timing T2 of the clock signal Clk_out2. A difference between the timing T2 and timing T1 is a time delay td2 of the described second signal path, as schematically indicated in FIG. 1A.

Further time delays indicated in FIG. 1A include time delays t_mt, t_sr, t_st, t_mr, t_mux, td3, of the clock tree CT1, clock tree CT2, clock tree CT3, clock tree CT4, multiplexer MUX1, flip-flop FF4. In at least one embodiment, the multiplexer MUX2 has a time delay similar to that of the multiplexer MUX1. However, the time delay of the multiplexer MUX2 is already included in time delay td2, and is not separately considered herein. In some embodiments, the multiplexer MUX2 is omitted, or the time delay of the multiplexer MUX2 is negligible, the time delay td2 corresponds to a time delay between the clock signal Clk_in2 and clock signal Clk_out2.

The clock signal Clk_out2 passes through the clock tree CT4 and arrives at the clock input of the flip-flop FF4 as the clock signal CLK4. The clock edge having the timing T2 of the clock signal Clk_out2 becomes, or corresponds to, a clock edge of the clock signal CLK4, e.g., a falling edge of the clock signal CLK4 because the clock signal CLK4 is an inverted clock signal. In response to the falling edge of the clock signal CLK4, the flip-flop FF4 outputs a corresponding edge of the signal D5 at a timing T3. A difference between the timing T3 and a timing of the falling edge of the clock signal CLK4 is the time delay td3 of the flip-flop FF4, as schematically indicated in FIG. 1A and FIG. 1B. Jitter J2 along the second signal path and through the clock tree CT4 and flip-flop FF4 generally occurs over the channel Ch4, as also schematically indicated in FIG. 1A.

FIG. 1B is a schematic timing diagram showing various signals in operations of the IC device 100 of FIG. 1A, in accordance with some embodiments.

The signals illustrated in FIG. 1B include the clock signal Clk_in1, clock signal CLK4, signal D5, clock signal CLK1, a clock signal CLK5_0, and a clock signal CLK5_1. The clock signal CLK5_0 is the clock signal CLK5 when the selection signal Sel1 has a value of logic “0”, and the multiplexer MUX1 is configured to output the inverted clock signal CLK1. The clock signal CLK5_1 is the clock signal CLK5 when the selection signal Sel1 has a value of logic “1”, and the multiplexer MUX1 is configured to output the clock signal CLK1.

As described herein, the clock signal Clk_in1 has a clock edge 151 at the timing T0. In the example configuration in FIG. 1B, the clock edge 151 is a rising edge. The clock signal Clk_in1 has a clock cycle T which is also the clock cycle of the other clock signals, i.e., clock signal CLK4, clock signal CLK1, clock signal CLK5_0, clock signal CLK5_1.

The clock signal CLK4 has a clock edge 152 at the timing T3. As illustrated in FIG. 1B, the clock signal CLK4 is an inverted clock signal relative to the clock signal Clk_in1, and has the clock edge 152, which is a falling edge, corresponding to the clock edge 151, which is a rising edge, of the clock signal Clk_in1. A time delay between the clock signal Clk_in1 and clock signal CLK4 is the time delay between the corresponding clock edges 151, 152, i.e., td1+td2+t_mr. In the example configuration in FIG. 1B, falling edges 152, 153, 154 or the like of the clock signal CLK4 are active clock edges in response to which the signal D5 is provided from the flip-flop FF4.

The signal D5 comprises a plurality of bits d0, d1, d2, or the like. Each of the bits d0, d1, d2, or the like, is provided from the flip-flop FF4 in response to a corresponding one among the active clock edges of the clock signal CLK4. For example, the bit do is provided in response to the clock edge 152, the bit d1 is provided in response to the clock edge 153, the bit d2 is provided in response to the clock edge 154, or the like.

The signal D5 comprises a signal portion 155 corresponding to the bit do. A start 157 of the signal portion 155 corresponding to the bit do occurs at the timing T3, with the time delay td3 from the corresponding clock edge 152. An end 159 of the signal portion 155, which is also a start of a subsequent signal portion of the signal D5 containing the bit d1, occurs with the same time delay td3 from the corresponding clock edge 153. A time difference between the start 157 and end 159 (i.e., a duration) of the signal portion 155 containing the bit do is the clock cycle T.

The clock signal CLK1, based on which the signal D5 input to the flip-flop FF5 is outputted as the signal D6, has clock edges 160, 162, 164 at an interval of a half of the clock cycle T. The clock edge 160 of the clock signal CLK1 is a rising edge corresponding to the clock edge 151 of the clock signal Clk_in1. A time delay between the clock signal Clk_in1 and clock signal CLK1 is the time delay between the corresponding clock edges 151, 160, i.e., the time delay t_mt of the clock tree CT1. The clock edges of the clock signal CLK1 subsequent to the clock edge 160 include a falling edge 162, and a rising edge 164. The falling edge 162 and rising edge 164 correspond to a timing ta and a timing tb for outputting, or reading out, the signal D5 from the flip-flop FF5 as the signal D6. The falling edge 162 is an example of one of a first edge and a second edge of the clock signal CLK1 for reading out the signal D5, and the rising edge 164 is an example of the other of the first edge and second edge of the clock signal CLK1 for reading out the signal D5. The timing ta or timing tb is selectable by a corresponding value of the selection signal Sel1.

For example, the selection signal Sel1 having a value of logic “0” corresponds to the timing ta being selected for reading out the signal D5. As described herein, in response to the selection signal Sel1 having a value of logic “0”, the clock signal CLK5_0 corresponding to the inverted clock signal CLK1 is output from the multiplexer MUX1 to the clock input of the flip-flop FF5. The clock signal CLK5_0 has a falling edge 171 corresponding to the rising edge 160 of the clock signal CLK1, and a rising edge 172 corresponding to the falling edge 162 of the clock signal CLK1. A time delay between the clock signal CLK1 and clock signal CLK5_0 is the time delay between the corresponding clock edges 160, 171, i.e., the time delay t_mux (not indicated in FIG. 1B) of the multiplexer MUX1. The rising edge 172 and subsequent rising edges 176, 177 of the clock signal CLK5_0 are active clock edges for the flip-flop FF5. Specifically, the rising edge 172 is the active clock edge in response to which the bit d0 of the signal D5 is read out by the flip-flop FF5 as part of the signal D6. A time delay between the rising edge 172 of the clock signal CLK5_0 and the corresponding falling edge 162 of the clock signal CLK1 is the time delay between the clock signal CLK5_0 and clock signal CLK1, and corresponds to the time delay t_mux of the multiplexer MUX1.

To ensure proper operation, certain requirements including setup time and hold time are to be met at the flip-flop FF5. Setup time and hold time are sometimes referred to as timing margins. The setup time is a predetermined minimum amount of time required for a signal at a data input of a flip-flop to be stable before an active clock edge arrives at a clock input of the flip-flop. The hold time is a predetermined minimum amount of time required for the signal at the data input to be stable after arrival of the active clock edge at the clock input. As illustrated in FIG. 1B, for the selected timing ta or the selection signal Sel1 being logic “0”, a setup time t_setup_ta of the flip-flop FF5 is the time difference between the start 157 of the signal portion 155 of the signal D5 and the rising edge 172 of the clock signal CLK5_0, whereas a hold time t_hold_ta of the flip-flop FF5 is the time difference between the end 159 of the signal portion 155 of the signal D5 and the rising edge 172 of the clock signal CLK5_0. The timing T3 of the start 157 of the signal portion 155 is represented as (T0+td1+td2+t_mr+td3), the timing of the end 159 of the signal portion 155 is represent as (T0+td1+td2+t_mr+td3+T), and t_setup_ta and t_hold_ta are determined by the following Equations:

t_setup_a=(T0+t_mt+T/2−Jpw+t_mux)−(T0+td1+td2+t_mr+td3)=T/2+t_mux−t_x−Jpw (1)

t_hold_a=(T0+td1+td2+t_mr+td3+T)−(T0+t_mt+T/2+Jpw+t_mux)=t_x+T/2−Jpw−t_mux (2)

In Equations (1)-(2), Jpw is duty cycle error (or clock duty cycle error), and t_x=td1+td2+t_mr+td3−t_mt. In some embodiments, the duty cycle error Jpw is omitted, or negligible. As illustrated in FIG. 1B, t_x is the time delay between the signal D5 and clock signal CLK1 in jitter-less situations. In some situations with clock jitter, the period jitter is the uncorrelated jitter from one or more clock buffers associated with the clock signal CLK1 and clock signal CLK4. Random jitter is assumed to have, for example, a distribution of σ_{1_4}=0.1 ps, with the peak to peak jitter of 2 ps with 20×σ_{1_4}.

For a further example, the selection signal Sel1 having a value of logic “1” corresponds to the timing tb being selected for reading out the signal D5. As described herein, in response to the selection signal Sel1 having a value of logic “1”, the clock signal CLK5_1 corresponding to the clock signal CLK1 is output from the multiplexer MUX1 to the clock input of the flip-flop FF5. The clock signal CLK5_1 has a rising edge 173 corresponding to the rising edge 160 of the clock signal CLK1, and a further rising edge 174 corresponding to the rising edge 164 of the clock signal CLK1. A time delay between the clock signal CLK1 and clock signal CLK5_1 is the time delay between the corresponding clock edges 160, 173, i.e., the time delay t_mux (not indicated in FIG. 1B) of the multiplexer MUX1. The rising edge 174 and subsequent rising edges 178, 179 of the clock signal CLK5_1 are active clock edges for the flip-flop FF5. Specifically, the rising edge 174 is the active clock edge in response to which the bit d0 of the signal D5 is read out by the flip-flop FF5. A time delay between the rising edge 174 of the clock signal CLK5_1 and the corresponding rising edge 164 of the clock signal CLK1 is the time delay between the clock signal CLK5_1 and clock signal CLK1, and corresponds to the time delay t_mux of the multiplexer MUX1.

As described herein, certain requirements including setup time and hold time are to be met at the flip-flop FF5 to ensure proper operation. As illustrated in FIG. 1B, for the selected timing tb or the selection signal Sel1 being logic “1”, a setup time t_setup_tb of the flip-flop FF5 is the time difference between the start 157 of the signal portion 155 of the signal D5 and the rising edge 174 of the clock signal CLK5_1, whereas a hold time t_hold_tb of the flip-flop FF5 is the time difference between the end 159 of the signal portion 155 of the signal D5 and the rising edge 174 of the clock signal CLK5_1. In particular, t_setup_tb and t_hold_tb are determined by the following Equations:

t_setup_tb=(T0+t_mt+t_mux+T)−(T0+td1+td2+t_mr+td3)=T+t_mux−t_x (3)

t_hold_tb=(T0+td1+td2+t_mr+td3+T)−(T0+t_mt+t_mux+T)=t_x-t_mux (4)

In a non-limiting example, at an operating frequency of 4 GHZ, T is 250 ps, and t_x is estimated to be at or below 60 ps over process-voltage-temperature (PVT) variations and supply droop for an advanced process. From the Equation (1), t_setup_a=T/2+t_mux−t_x−Jpw, corresponding to a timing margin of about 60 ps, with T/2=125 ps and t_x at or below 60 ps. From Equation (2), t_hold_a=t_x+T/2−Jpw−t_mux, corresponding to a timing margin of about 180 ps which is more than enough to address various timing-related concerns discussed herein.

When t_x is approaching T/2 or greater than T/2, i.e., the signal D5 in FIG. 1B shifts further to the right hand side, the timing tb provides better timing margins than the timing ta, and is selected in one or more embodiments for reading out the signal D5. For example, from Equation (3), t_setup_b=T+t_mux−t_x, the timing tb provides the best setup time and hold time when t_x is near T/2 (or 125 ps in the above non-limiting example).

When one of the setup time t_setup_ta and hold time t_hold_ta is smaller than the corresponding predetermined minimum amount of time, signal stability and/or data accuracy are affected, and it is not suitable to use the timing ta, or the corresponding clock signal CLK5_0, for reading out the signal D5. Similarly, when one of the t_setup_tb and t_hold_tb is smaller than the corresponding predetermined minimum amount of time, it is not suitable to use the timing tb, or the corresponding clock signal CLK5_1, for reading out the signal D5.

In at least one embodiment, it is advantageous that the corresponding setup time and hold time are equal or as close to each other as possible, to read out the signal D5 by an active clock edge (e.g., rising edge 172 or rising edge 174) at, or close to, the “eye” or center of the corresponding signal portion (e.g., signal portion 155) of the signal D5. Such a reading out at the “eye” or center is associated with the setup time and hold time both being equal to a half of the clock cycle, i.e., T/2. These timing margins are optimal, and make it possible to overcome various concerns, including, but not limited to, jitter, skew mismatch, channel impairment, clock duty cycle error, or the like.

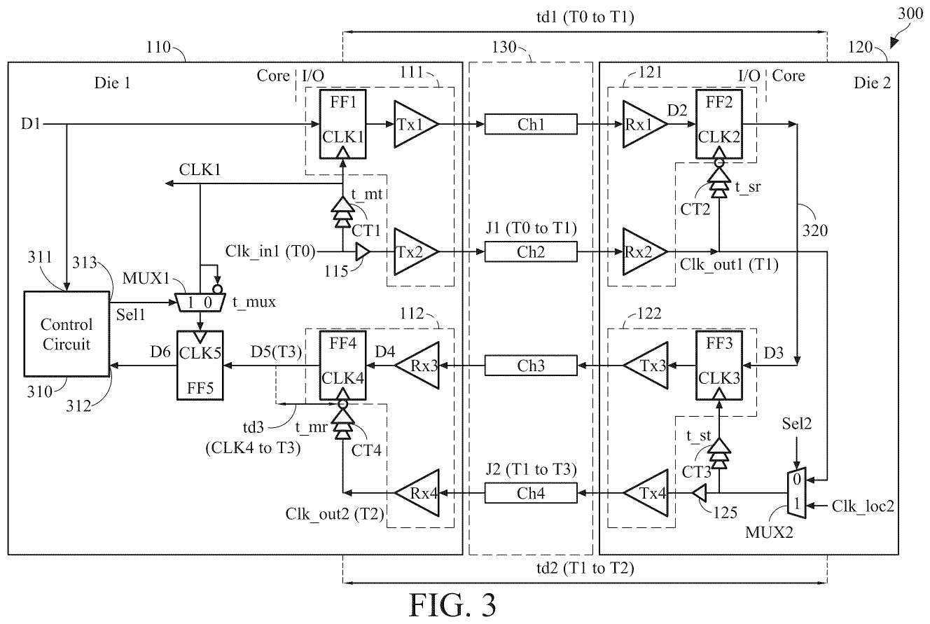

In some embodiments, a selection of either the timing ta or the timing tb corresponds to a selection of using either the falling edges or the rising edges of the clock signal CLK1 for reading out the signal D5 through the flip-flop FF5 and/or a selection of supplying either the inverted clock signal CLK1 or the clock signal CLK1 to the clock input of the flip-flop FF5. In at least one embodiment, a selection whether to use the timing ta or timing tb at the flip-flop FF5 for reading out the signal D5, is made at the design stage by determining or estimating the corresponding setup times and hold times using one or more of the Equations (1)-(4). As can be seen from the Equations (1)-(4), most components, e.g., t_x, t_mux, T, are known or determinable based on various physical and/or electrical characteristics of the circuit elements along the signal path(s). Based on the determined setup times and hold times, the timing ta or timing tb with the better determined setup time and hold time (e.g., with the smaller difference between the setup time and hold time) is selected. A value (e.g., logic “0” or logic “1”) of the selection signal Sel1 corresponding to the selected timing ta or timing tb is stored in a storage circuit coupled to the selection input of the multiplexer MUX1, as described with respect to FIG. 2. Alternatively or additionally, in some embodiments, a selection whether to use the timing ta or timing tb at the flip-flop FF5 for reading out the signal D5, is made during fabrication and/or operation, by a calibration process, as described with respect to FIG. 3.

In some embodiments, by returning the clock signal Clk_out1 received at the semiconductor die 120 back to the semiconductor die 110 and also using the returned clock signal (i.e., clock signal Clk_in2) to send data from the semiconductor die 120 to the semiconductor die 110, it is possible to take advantage of the inventor's observation that the signal paths corresponding to jitter J1 and jitter J2 have the same, or substantially the same, intrinsic delays. Thus, it is not necessary in one or more embodiments to provide a delay matching arrangement on the semiconductor die 110 as in some other approaches. In some embodiments, data sampling, or reading out, of the signal D2 and/or the signal D4 from the corresponding flip-flop FF2 and/or flip-flop FF4 has timing margins which are optimal, more robust and/or better than some other approaches with a delay matching arrangement on the die with the master clock.

In some embodiments, by including the flip-flop FF5 and multiplexer MUX1 in the semiconductor die 110, it is possible to enable best possible timing margins for reading out the signal D5. Specifically, due to the elongated signal path of the clock signal Clk_in1 from the semiconductor die 110 to the semiconductor die 120 and then back to the semiconductor die 110, the time delays along this elongated signal path, e.g., td1+td2+td3, are also large. Such large time delays td1+td2+td3 in some situations reduce an otherwise available timing margin (e.g., a setup time or a hold time) to a low amount of time that is potentially insufficient to accommodate one or more issues, such as jitter, skew mismatch, channel impairment, clock duty cycle error, or the like. By providing through the multiplexer MUX1 the availability of two options for reading out the signal D5 in response to the rising edges, or in response to the falling edges, of the clock signal CLK1, it is possible in one or more embodiments to select the better of the two options, i.e., the option with the smaller difference between the setup time and hold time, for reading the signal D5, to achieve best possible timing margins without being affected by duty cycle error and/or jitter.

As can be seen from FIG. 1B, reading out the signal D5 based on the timing ta, or in response to the falling edges of the clock signal CLK1, is associated with a latency of T/2 (half cycle), whereas reading out the signal D5 based on the timing tb, or in response to the rising edges of the clock signal CLK1, is associated with a latency of T (full cycle). In some embodiments, when the timing margins of the two options are the same or substantially the same, e.g., the difference between the setup time and hold time is the same or substantially the same for both options, the timing ta is preferred and selected over the timing tb due to the shorter latency.

In some embodiments, the flip-flop FF5 and multiplexer MUX1 are omitted, for example, where td1+td2+td3 is small compared the clock cycle T.

In some embodiments, the clock signal Clk_in1 transmitted between the semiconductor die 110 and semiconductor die 120 provides one common clock domain across both the semiconductor die 110 and semiconductor die 120. As a result, it is possible in one or more embodiments to avoid clock synchronization which is required in other approaches which use two different and/or independent clock domains each for one of the coupled dies. In such other approaches, various circuits for clock synchronization, e.g., first-in-first-out (FIFO) circuits associated with the receiving circuit of each die, are required and potentially cause an increase of power consumption and/or latency. An IC device in accordance with some embodiments is free of such FIFO circuits on any of the coupled semiconductor dies, while enabling a D2D interface with one or more advantages including, but not limited to, minimal circuit overhead, reduced circuit complexity, reduced latency, saved power and/or area for FIFO circuits, or the like.

In some embodiments, the described clock arrangement for the IC device 100 is advantageously suitable for situations where one of the semiconductor dies does not have its own clock and is configured to operate based on clock signals provided by the other semiconductor die. In an example of such situations, the semiconductor die 110 is a logic die, whereas the semiconductor die 120 is a memory die with no clock. The logic die and the memory die share one clock domain provided by the logic die (e.g., by the clock signal Clk_in1) while avoiding FIFO circuit latency, in one or more embodiments.

In some embodiments, the provision of the multiplexer MUX2 enhances clock arrangement flexibility and/or compatibility. The multiplexer MUX2 permits controllable switching between a common clock domain mode and a separate clock domain mode, in accordance with the controllable value of the selection signal Sel2. The common clock domain mode is when the clock signal Clk_in1 corresponding to a master clock signal is provided from the semiconductor die 110 to the semiconductor die 120 to be sent back with data from the semiconductor die 120 to the semiconductor die 110, with one or more achievable advantages as described herein. The separate clock domain mode is when the semiconductor die 120 uses a separate (or independent) clock signal Clk_loc2 for communications with the semiconductor die 110 in specific applications or situations.

FIG. 2 is a schematic circuit diagram of a clock management circuit 200, in accordance with some embodiments. In some embodiments, the clock management circuit 200 is part of an IC device corresponding to the IC device 100. Components in FIG. 2 having corresponding components in one or more of the other figures are designated by the same reference numerals as in the other figures.

The clock management circuit 200 comprises the multiplexer MUX1 as described with respect to FIG. 1A, and a storage circuit 205. In the example configuration in FIG. 2, the storage circuit 205 comprises a register. Other storage circuit configurations are within the scopes of various embodiments. The storage circuit 205 is configured to store therein at least a value of the selection signal Sel1. The storage circuit 205 is coupled to the selection input of the multiplexer MUX1 to supply the stored value of the selection signal Sel1 to the multiplexer MUX1. As a result, the multiplexer MUX1 is configured by the stored value in the storage circuit 205 to correspondingly output either the clock signal CLK1 (in response to the stored value being logic “1”) or the inverted clock signal CLK1 (in response to the stored value being logic “0”) as the clock signal CLK5 to the flip-flop FF5 (not shown in FIG. 2).

In some embodiments, the value stored in the storage circuit 205 is determined at the design stage, e.g., by determining or estimating the setup times and hold times corresponding to the timing ta and timing tb using one or more of the Equations (1)-(4). Based on the determined setup times and hold times, the timing ta or timing tb with the better determined setup time and hold time is selected, and the value of the selection signal Sel1 corresponding to the selected timing ta or timing tb is stored in the storage circuit 205. Alternatively or additionally, in some embodiments, the value stored in the storage circuit 205 is determined and/or updated, periodically and/or on demand, during fabrication and/or operation of the IC device containing the clock management circuit 200, e.g., by a calibration process, as described with respect to FIG. 3. One or more advantages described herein are achievable by the clock management circuit 200 and/or the IC device containing the clock management circuit 200, in accordance with some embodiments.

FIG. 3 is a schematic circuit diagram of an IC device 300, in accordance with some embodiments. In some embodiments, the IC device 300 corresponds to one or more IC devices described with respect to FIGS. 1A-1B, 2. Components in FIG. 3 having corresponding components in one or more of the other figures are designated by the same reference numerals as in the other figures.

In addition to components described with respect to the IC device 100, the IC device 300 further comprises a control circuit 310 in the semiconductor die 110, and an electrical connection 320 coupling the output of the flip-flop FF2 to the input of the flip-flop FF3 in the semiconductor die 120. In some embodiments, the control circuit 310 is part of the functional circuit of the semiconductor die 110. The control circuit 310 comprises a first input 311 configured to receive the signal D1 to be sent to the semiconductor die 120, a second input 312 coupled to the output of the flip-flop FF5 to receive the signal D6, and an output 313 coupled to the selection input of the multiplexer MUX1. In some embodiments, the control circuit 310 itself sends the signal D1 to the flip-flop FF1 to be sent to the semiconductor die 120. In some embodiments, the electrical connection to provide the signal D1 to the first input 311, the electrical connection to provide the signal D6 to the second input 312, and the electrical connection 320 are temporarily established, e.g., by closing one or more switches (not shown), during a calibration process as described. Upon completion of the calibration process, the temporarily established electrical connections are disconnected, e.g., by opening the one or more switches, for normal operation.

In the calibration process in accordance with some embodiments, the signal D1, which is sent from or to the control circuit 310, comprises a test signal. The test signal is sent from the semiconductor die 110 over the channel Ch1 to the semiconductor die 120, then turned around through the electrical connection 320, and sent from the semiconductor die 120 over the channel Ch3 back to the semiconductor die 110. The clock signal Clk_in1 is transmitted from the semiconductor die 110 over the channel Ch2 to the semiconductor die 120, and then returned over the channel Ch4 back to the semiconductor die 110 as described with respect to the IC device 100.

In at least one embodiment, the test signal comprises several test patterns. For example, a test pattern comprises a predetermined or known series of bits. If back and forth communications between the semiconductor die 110 and semiconductor die 120 are properly configured and operated, it is expected that the returned test patterns which are read out from the flip-flop FF5 and provided to the control circuit 310 as the signal D6 will be identical to the original test patterns included in the signal D1 and already known to the control circuit 310.

In some embodiments, by sending a first value of the selection signal Sel1 through the output 313 to the multiplexer MUX1, the control circuit 310 sets the flip-flop FF5 to read out a first returned test pattern of the signal D5 in response to falling edges of the clock signal CLK1. Next, by sending a different, second value of the selection signal Sel1 through the output 313 to the multiplexer MUX1, the control circuit 310 sets the flip-flop FF5 to read out a second returned test pattern of the signal D5 in response to rising edges of the clock signal CLK1. Each of the two returned test patterns read-out correspondingly based on different clock edges of the clock signal CLK1 is compared with the corresponding known or original test pattern included in the signal D1. A known or original test pattern included in the signal D1 is an example of first data. A returned test pattern read out from the signal D5 is an example of second data.

In at least one embodiment, there is a situation when one of the two returned test patterns fails while the other returned test pattern passes the comparison test. For example, the first returned test pattern differs from the corresponding original test pattern and is determined by the control circuit 310 as failing the test, whereas the second returned test pattern is identical to the corresponding original test pattern and is determined by the control circuit 310 as passing the test. The value (e.g., logic “1”) of the selection signal Sel1 corresponding to the clock edges (e.g., rising edges) of the clock signal CLK1 used to read out the passing returned test pattern is sent by the control circuit 310 through the output 313 to the selection input of the multiplexer MUX1 to configure the flip-flop FF5 to thereafter use the rising edges of the clock signal CLK1 for reading out further signals sent from the semiconductor die 120 to the semiconductor die 110 in communications during normal operation.

In some embodiments, there is a situation when both the returned test patterns pass the comparison test. In such a situation, the control circuit 310 selects the falling edges of the clock signal CLK1 for communications during normal operation. A reason, as described herein, is that the latency (T/2) caused by data reading based on falling edges of the clock signal CLK1 is shorter than the latency (T) caused by data reading based on rising edges of the clock signal CLK1. The value (e.g., logic “0”) of the selection signal Sel1 corresponding to the falling edges of the clock signal CLK1 is sent by the control circuit 310 through the output 313 to the selection input of the multiplexer MUX1 to configure the flip-flop FF5 to thereafter use the falling edges of the clock signal CLK1 for reading out further signals sent from the semiconductor die 120 to the semiconductor die 110 in communications during normal operation.

In some embodiments, there is a situation when both the returned test patterns fail the comparison test. In such a situation, the control circuit 310 re-runs the test one or more times, and if the returned test patterns still fail the comparison test, the control circuit 310 notifies external equipment and/or a human operator that the IC device 300 fails a D2D communication test and should be examined further, e.g., for repair.

In at least one embodiment, the described calibration process ends with the selection signal Sel1 being determined or set, by the control circuit 310, to a particular value corresponding to falling edges or rising edges of the clock signal CLK1 to be subsequently used by the flip-flop FF5 to read our further signals sent from the semiconductor die 120 to the semiconductor die 110 during normal operation.

In some embodiments, the control circuit 310 comprises a storage circuit corresponding to the storage circuit 205. Upon completion of the calibration process, the control circuit 310 stores the determined (or set) value of the selection signal Sel1 into the storage circuit to configure the flip-flop FF5, e.g., as described with respect to FIG. 2.

In at least one embodiment, the control circuit 310 is configured to execute the calibration process periodically or on demand, and to update the set value of the selection signal Sel1 as necessary. A reason is to ensure correct and/or efficient communication between the semiconductor die 110 and semiconductor die 120 despite PVT variations. One or more advantages described herein are achievable by the IC device 300, in accordance with some embodiments.

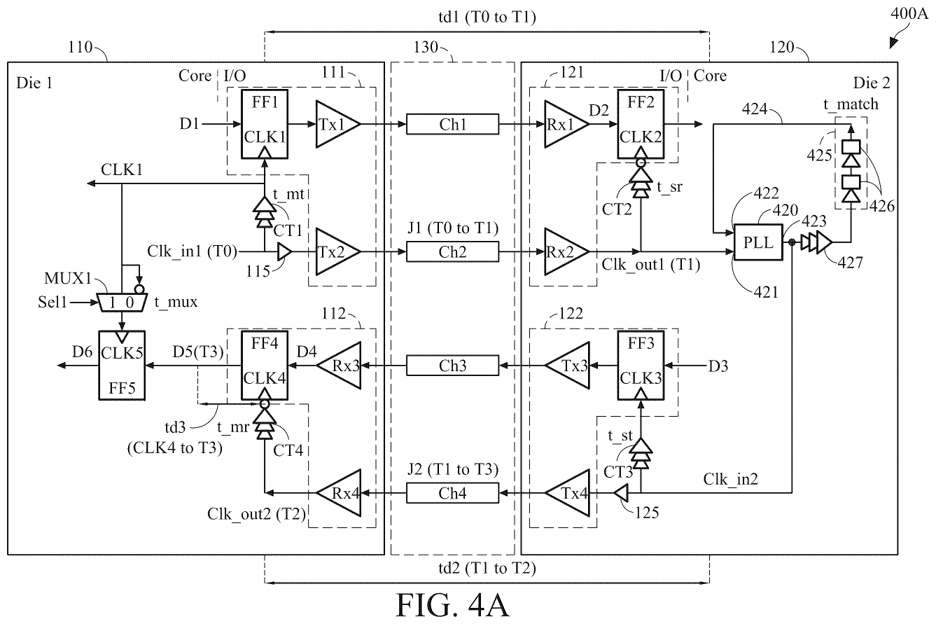

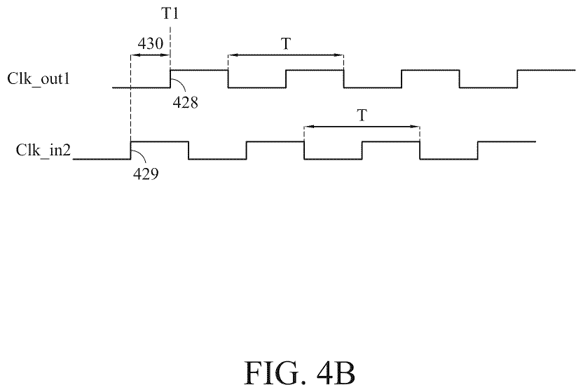

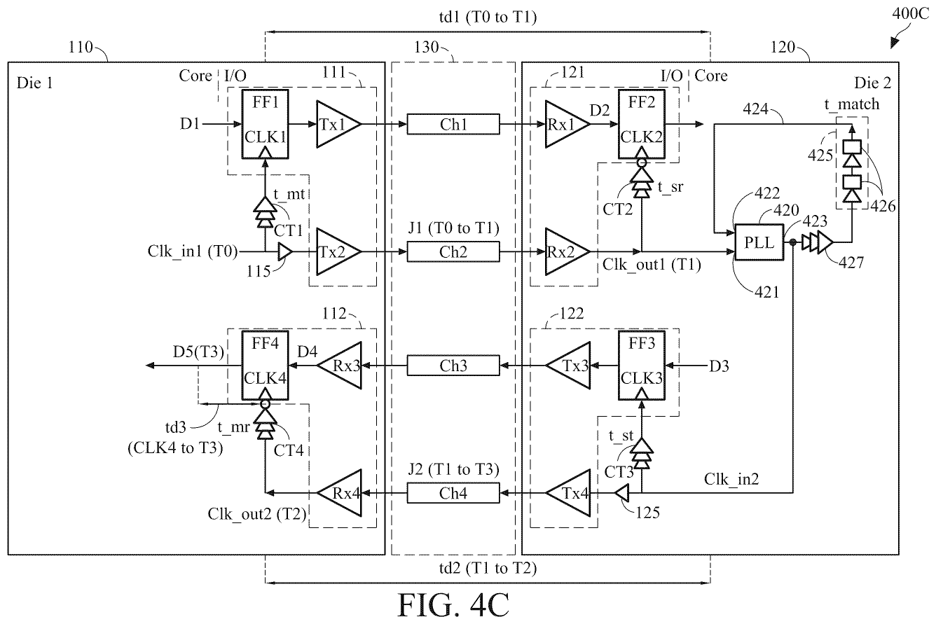

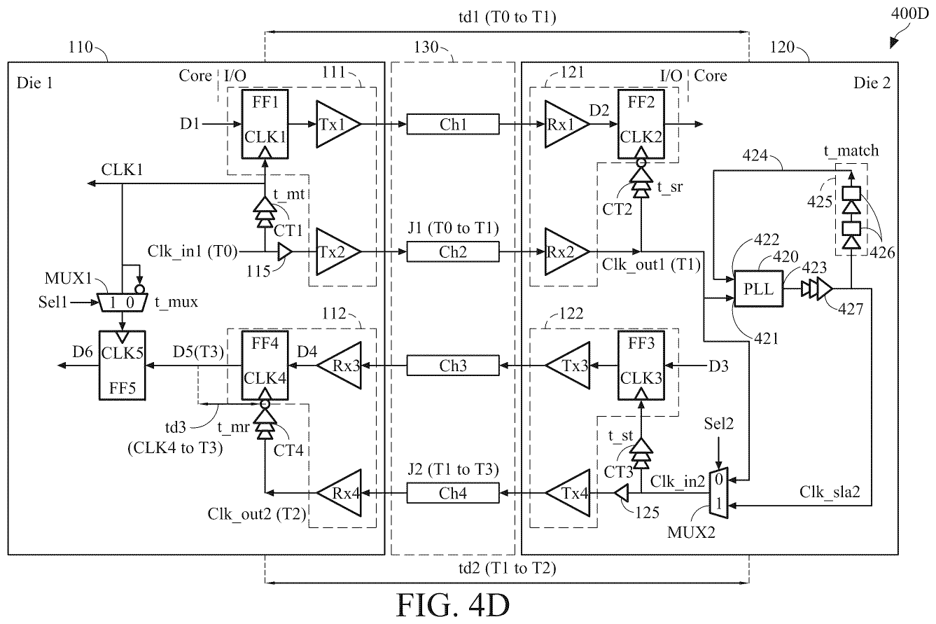

FIG. 4A is a schematic circuit diagram of an IC device 400A, in accordance with some embodiments. In some embodiments, the IC device 400A corresponds to one or more of the IC devices described with respect to FIGS. 1A-1B, 2-3. Components in FIG. 4A having corresponding components in one or more of the other figures are designated by the same reference numerals as in the other figures.

In addition to components described with respect to the IC device 100, the IC device 400A further comprises a PLL 420, a delay circuit 425, and a clock tree 427; however, the multiplexer MUX2 of the IC device 100 is omitted from the IC device 400A. The PLL 420 comprises a reference input 421, a feedback input 422, and an output 423. The reference input 421 is coupled to the output of the clock input buffer Rx2 to receive the clock signal Clk_out1 received from the semiconductor die 110. A feedback path 424 is coupled between the feedback input 422 and the output 423. The feedback path 424 comprises therein the delay circuit 425. In the example configuration in FIG. 4A, the clock tree 427 is coupled between the output 423 and an input of the delay circuit 425, whereas an output of the delay circuit 425 is coupled to the feedback input 422. In at least one embodiment, the clock tree 427 is omitted. The PLL 420 is configured to provide, at the output 423, the clock signal Clk_in2 corresponding to the clock signal Clk_out1 at the reference input 421.

The delay circuit 425 comprises one or more circuit elements 426 configured to impact a time delay t_match to a feedback signal on the feedback path 424 from the output 423 to the feedback input 422. Examples of the circuit elements 426 include, but are not limited to, buffers, drivers, inverters, or the like. The time delay t_match in the feedback path 424 causes the clock signal Clk_in2 at the output 423 of the PLL 420 to have a corresponding phase lead relative to the clock signal Clk_out1 at the reference input 421 of the PLL 420, as described with respect to FIG. 4B.

In at least one embodiment, the time delay t_match of the delay circuit 425 corresponds to a sum of the time delay td1 ad the time delay td2. In at least one embodiment, t_match=td1+td2. In some embodiments, it is difficult to bring t_match to the exact value of td1+td2 due to, e.g., various factors and/or variations. In at least one embodiment, it is possible to match t_match as close as practical to td1+td2. For example, as described herein with respect to Equations (1)-(4), various components in those Equations, including td1 and td2, are known or determinable based on various physical and/or electrical characteristics of the corresponding circuit elements. For example, the time delay td1 is determinable from various physical and/or electrical characteristics of the clock driver 115, the clock output buffer Tx2, the D2D interface structure configuring the channel Ch2, and the clock input buffer Rx2. Similarly, the time delay td2 is determinable from various physical and/or electrical characteristics of the clock driver 125, the clock output buffer Tx4, the D2D interface structure configuring the channel Ch4, the clock input buffer Rx4. In at least one embodiment, the circuit elements contributing to the time delay td1 are similar to if not the same as the circuit elements contributing to the time delay td2, and the time delay td1 is considered the same as the time delay td2. In at least one embodiment, at the design stage, td1 and td2 are calculated, and based on the sum td1+td2, the delay circuit 425 is configured to include a sufficient number and/or types of circuit elements that provide t_match equal or substantially equal to td1+td2.

FIG. 4B is a schematic timing diagram showing the clock signal Clk_out1 and clock signal Clk_in2 in operations of the IC device 400A, in accordance with some embodiments. As described with respect to FIGS. 1A-1B, the clock edge 151 having the timing T0 of the clock signal Clk_in1 becomes, or corresponds to, a clock edge having a timing T1 of the clock signal Clk_out1. The clock edge having the timing T1 of the clock signal Clk_out1 is designated as clock edge 428 in FIG. 4B. The clock signal Clk_out1 serves as a reference signal based on which the PLL 420, with the delay circuit 425 in the feedback path 424 thereof, outputs the clock signal Clk_in2. The clock edge 428 of the clock signal Clk_out1 corresponds to a clock edge 429 of the clock signal Clk_in2. As can be seen in FIG. 4B, the clock edge 429 is earlier, by a time period or phase lead 430, than the corresponding clock edge 428. In other words, the clock signal Clk_in2 at the output 423 of the PLL 420 has the phase lead 430 relative to the clock signal Clk_out1 at the reference input 421 of the PLL 420. In at least one embodiment, the phase lead 430 is equal to the time delay t_match of the delay circuit 425. In some embodiments, due to various factors and/or variations, the phase lead 430 is slightly different from, but still fairly close to, the time delay t_match.

Returning to FIG. 4A, the phase lead 430 of the clock signal Clk_in2 relative to the clock signal Clk_out1 provides the effect of shifting the timings and signals that follow the clock signal Clk_in2 “backwards” in time by an amount of time corresponding to the phase lead 430, in one or more embodiments. For example, in at least one embodiment, the timing diagram in FIG. 1B is applicable to describe the timings and signals in FIG. 4A, with the difference in that the clock signal CLK4 and signal D5 are shifted “backwards” in time or to the left in FIG. 1B by an amount of time corresponding to the phase lead 430. In some embodiments, the amount of time by which the clock signal CLK4 and signal D5 are shifted is the phase lead 430 minus jitter, including Rj and/or Dj, exhibited by the PLL 420 at the signal D5. The described “backwards” shifting improves timing margins at the flip-flop FF5, in one or more embodiments.

In at least one embodiment, as described herein, the delay circuit 425 is configured to provide the time delay t_match based on the sum of td1+td2. For example, t_match is equal, or substantially equal, to td1+td2. As a result, the PLL 420 provides the phase lead 430 equal, or substantially equal, to td1+td2, and the clock signal CLK4 and signal D5 are shifted “backwards” in time by an amount of time roughly matching the sum of td1+td2. As described herein, an exact matching of td1+td2 is difficult due to various factors and/or variations, including, but not limited to, jitter caused by the PLL 420 as described herein. The described process of configuring the delay circuit 425 to have t_match based on td1+td2 is an approach, in one or more embodiments, to shift the clock signal CLK4 and signal D5 “backwards” in time by an amount of time roughly matching td1+td2. This arrangement improves timing margins at the flip-flop FF5, in one or more embodiments.

In some embodiments, the described configuration with the PLL 420 on the semiconductor die 120 is useful for Si-testing purposes, especially where the total jitter (Rj+Dj) exhibited by the PLL 420 at the signal D5 is much smaller than td1+td2. In some embodiments, Si-testing comprises testing manufactured IC devices for functional correctness in a setup corresponding to the actual working environment.

The described arrangement with the PLL 420 and the delay circuit 425 in the feedback path 424 is an example of a second circuit configured to receive a clock signal (e.g., the clock signal Clk_out1), and to output another clock signal (e.g., the clock signal Clk_in2) corresponding to the received clock signal and having a phase lead relative to the received clock signal. Other configurations for such a second circuit are within the scopes of various embodiments. In some embodiments, the second circuit is an example of a clock management circuit, or at least a part thereof. One or more advantages described herein are achievable by the IC device 400A, in accordance with some embodiments.

FIGS. 4C, 4D are schematic circuit diagrams of corresponding IC devices 400C, 400D, in accordance with some embodiments. In some embodiments, the IC devices 400C, 400D correspond to one or more of the IC devices described with respect to FIGS. 1A-1B, 2-3, 4A-4B. Components in one or more of FIGS. 4C-4D having corresponding components in one or more of the other figures are designated by the same reference numerals as in the other figures.

In FIG. 4C, the IC device 400C is similar to the IC device 400A, with a difference that the multiplexer MUX1 and flip-flop FF5 of the IC device 400A are omitted from the IC device 400C. As described herein, the first circuit comprising the multiplexer MUX1 and flip-flop FF5 on the semiconductor die 110 and the second circuit comprising the PLL 420 and delay circuit 425 on the semiconductor die 120 are both configured to improve timing margins for reading out data received at the transmitting circuit 122 of the semiconductor die 120. In some embodiments, both the first circuit and the second circuit are included for timing margin improvements, for example, as described with respect to the example configuration of FIG. 4A. In at least one embodiment, one of the first circuit and the second circuit is sufficient for timing margin improvements, and the other of the first circuit and the second circuit is omitted. For example, the second circuit on the semiconductor die 120 is omitted in the example configuration of FIG. 1A. For another example, the first circuit on the semiconductor die 110 is omitted in the example configuration of FIG. 4C.

In FIG. 4D, the IC device 400D is similar to the IC device 400A, but additionally comprises the multiplexer MUX2. As described with respect to FIG. 1A, the multiplexer MUX2 comprises a first input (with label “0”) coupled to the output of the clock input buffer Rx2 to receive the clock signal Clk_out1, a selection input configured to receive a selection signal Sel2, and an output coupled to the flip-flop FF3 and clock output buffer Tx4 correspondingly through the clock tree CT3 and clock driver 125. The multiplexer MUX2 further comprises a second input (with label “1”) coupled to the clock tree 427 and the input of the delay circuit 425 to receive a clock signal Clk_sla2. The clock signal Clk_sla2 in the IC device 400D corresponds to the clock signal Clk_in2 in the IC device 400C.

In a manner similar to that described with respect to FIG. 1A, depending on a value of the selection signal Sel2, the multiplexer MUX2 is configured to output the clock signal Clk_in2 corresponding to either the clock signal Clk_out1 or the clock signal Clk_sla2. For example, in response to the selection signal Sel2 having a value of logic “0”, the multiplexer MUX2 is configured to output the clock signal Clk_in2 corresponding to the clock signal Clk_out1. In this configuration, the IC device 400D is configured and operable in a manner similar to the IC device 100 with the selection signal Sel2 having logic “0”, as described herein. For another example, in response to the selection signal Sel2 having a value of logic “1”, the multiplexer MUX2 is configured to output the clock signal Clk_in2 corresponding to the clock signal Clk_sla2. In this configuration, the IC device 400D is configured and operable in a manner similar to the IC device 400A, as described herein. In at least one embodiment, the multiplexer MUX2 provides further options for controllable clock management, to achieve proper and/or optimal timing margins for reading data output by the receiving circuit 112. One or more advantages described herein are achievable by one or more of the IC devices 400C, 400D, in accordance with some embodiments.

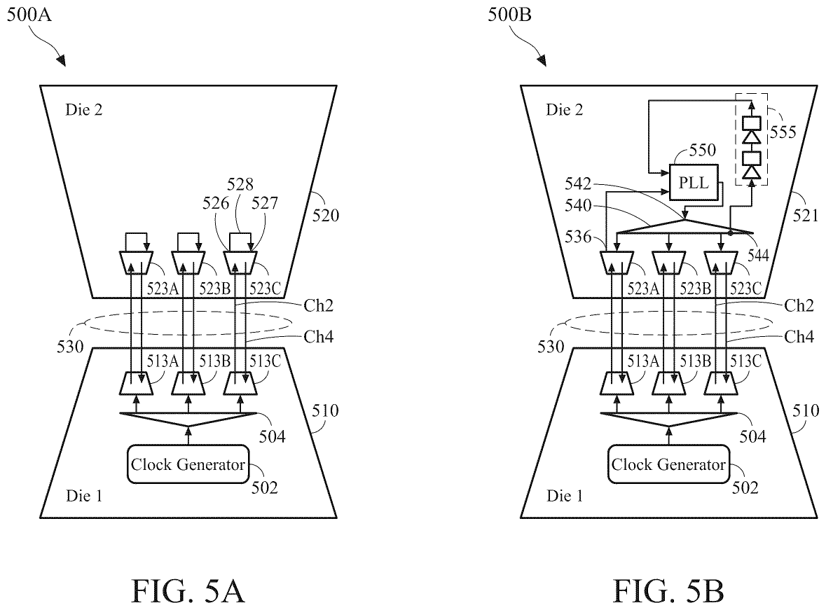

FIGS. 5A, 5B are schematic circuit diagrams of corresponding IC devices 500A, 500B, in accordance with some embodiments. In some embodiments, the IC devices 500A, 500B correspond to one or more of the IC devices described with respect to FIGS. 1A-1B, 2-3, 4A-4D. Components in one or more of FIGS. 5A-5B having corresponding components in one or more of the other figures are designated by the same reference numerals as in the other figures.

In FIG. 5A, the IC device 500A comprises a first semiconductor die 510 (labelled as “Die 1”) and a second semiconductor die 520 (labelled as “Die 2”) electrically and physically coupled to each other by a plurality of die-to-die (D2D) interface structures 530. In some embodiments, the semiconductor die 510, semiconductor die 520, interface structures 530 correspond to the semiconductor die 110, semiconductor die 120, interface structures 130. For simplicity, various components of the semiconductor die 510 and semiconductor die 520, e.g., one or more functional circuits, one or more data I/O circuits, or the like, are omitted in FIG. 5A.

The semiconductor die 510 comprises a clock generator (or clock source) 502, a clock tree 504, and a plurality of clock I/O circuits 513A-513C. The number (three) of clock I/O circuits of the semiconductor die 510 is an example. Other numbers of clock I/O circuits are within the scopes of various embodiments. Examples of the clock source 502 and clock tree 504 are described with respect to FIG. 7. Examples of the clock I/O circuits 513A-513C are described with respect to FIG. 1A. For example, in at least one embodiment, each of the clock I/O circuits 513A-513C comprises a clock output buffer corresponding to the clock output buffer Tx2, and a clock input buffer corresponding to the clock input buffer Rx4.

The semiconductor die 520 comprises a plurality of clock I/O circuits 523A-523C. Examples of the clock I/O circuits 523A-523C are described with respect to FIG. 1A. For example, in at least one embodiment, each of the clock I/O circuits 523A-523C comprises a clock output buffer corresponding to the clock output buffer Tx4, and a clock input buffer corresponding to the clock input buffer Rx2.

Each of the clock I/O circuits 523A-523C of the semiconductor die 520 is coupled to a corresponding one of the clock I/O circuits 513A-513C of the semiconductor die 510 through a corresponding pair of interface structures 530. For example, the clock input buffer of the clock I/O circuit 523C is coupled to the clock output buffer of the clock I/O circuit 513C through one interface structure (or channel) Ch2, and the clock output buffer of the clock I/O circuit 523C is coupled to the clock input buffer of the clock I/O circuit 513C through another interface structure (or channel) Ch4.

For each of the clock I/O circuits 523A-523C of the semiconductor die 520, the output (e.g., 526) of the clock input buffer is coupled to the input (e.g., 527) of the clock output buffer by an electrical connection 528. In some embodiments, this configuration corresponds to one or more of the configurations described with respect to FIGS. 1A, 4D where the selection signal Sel2 for the multiplexer MUX2 is logic “0”. In at least one embodiment, the IC device 500A is configured to operate in one or more manners described with respect to one or more of FIGS. 1A-4D. One or more advantages described herein are achievable by the IC device 500A, in accordance with some embodiments.

In FIG. 5B, the IC device 500B comprises the first semiconductor die 510 and a second semiconductor die 521 electrically and physically coupled to each other by a plurality of D2D interface structures 530. The semiconductor die 510 and interface structures 530 are as described with respect to FIG. 5A.

The semiconductor die 521 comprises a plurality of clock I/O circuits 523A-523C as described with respect to FIG. 5A. The semiconductor die 521 further comprises a clock tree 540, a PLL 550, and a delay circuit 555. In some embodiments, the clock tree 540, PLL 550, and delay circuit 555 correspond to the clock tree 427, PLL 420, delay circuit 425 described with respect to one or more of FIGS. 4A-4D.

An example of the clock tree 540 is described with respect to FIG. 7. For example, the clock tree 540 comprises a top tier or upper tier 542, one or more lower tiers (not shown), a clock mesh structure 544. In at least one embodiment, the clock tree 540 further comprises post-mesh clock trees coupled to the clock mesh structure 544. For simplicity, such post-mesh clock trees are considered parts of the clock mesh structure 544. A clock signal received at the upper tier 542 is propagated through the one or more lower tiers to the clock mesh structure 544 where the propagated clock signal is delivered to various components including the clock I/O circuits 523A-523C. In some embodiments, the clock tree 504 on the semiconductor die 510 is configured and/or operable in a similar manner.

At least one of the clock I/O circuits 523A-523C, e.g., the clock I/O circuit 523A, has an output 536 of the corresponding clock input buffer coupled to a reference input of the PLL 550. An output of the PLL 550 is coupled to the upper tier 542 of the clock tree 540. An input of the delay circuit 555 is coupled to a point on the clock mesh structure 544. An output of the delay circuit 555 is coupled to a feedback input of the PLL 550. In some embodiments, this configuration corresponds to one or more of the configurations described with respect to FIGS. 4A, 4C, and FIG. 4D where the selection signal Sel2 for the multiplexer MUX2 is logic “1”. In some embodiments, the semiconductor die 520 and the semiconductor die 521 are implemented by a single semiconductor die which is controllably switchable between the configuration of the semiconductor die 520 and the configuration of the semiconductor die 521. In at least one embodiment, the IC device 500B is configured to operate in one or more manners described with respect to one or more of FIGS. 1A-4D. One or more advantages described herein are achievable by the IC device 500B, in accordance with some embodiments.

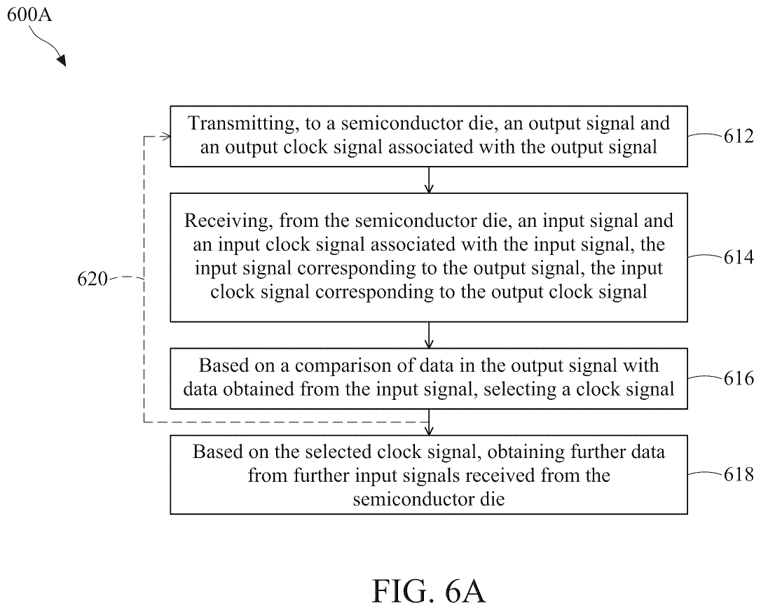

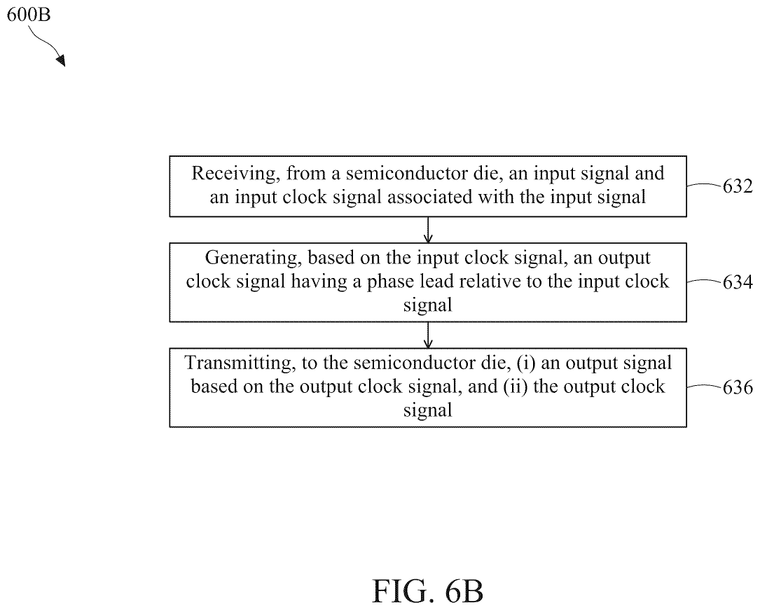

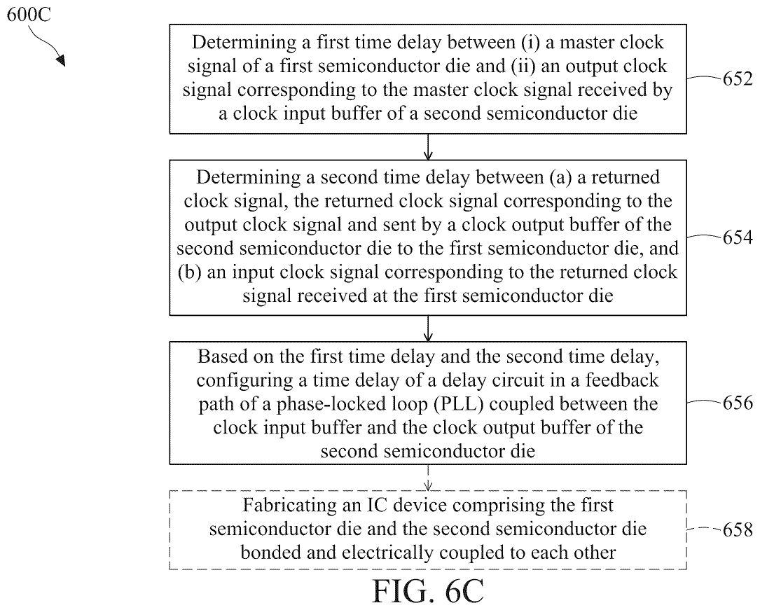

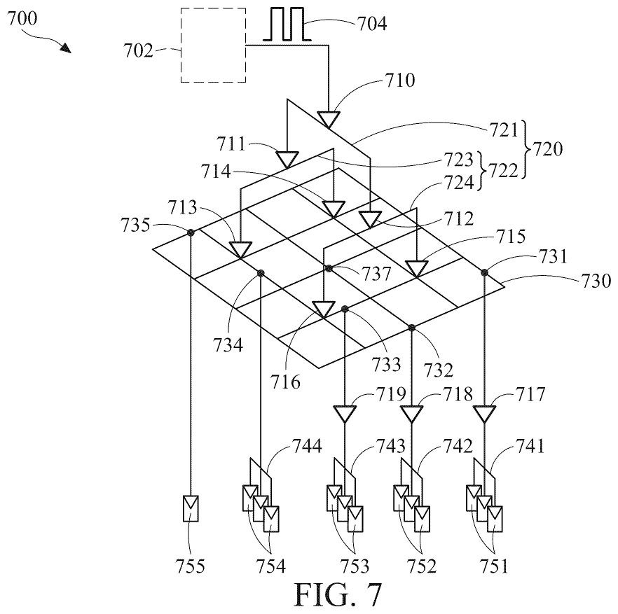

FIG. 6A is a flow chart of a method 600A, in accordance with some embodiments. In some embodiments, the method 600A comprises a calibration process as described with respect to FIG. 3. In at least one embodiment, the method 600A is performed at an IC device corresponding to one or more of the IC devices described with respect to FIGS. 1, 4A, 4D, 5A, 5B. The method 600A comprises operations 612, 614, 616, 618.

At operation 612, an output signal and an output clock signal associated with the output signal are transmitted to a semiconductor die. For example, as described with respect to FIG. 3, in at least one embodiment, the output signal comprises the signal D1, which is a test signal, sent from the semiconductor die 110 over the channel Ch1 to the semiconductor die 120. The output clock signal comprises the clock signal Clk_in1 sent along with the signal D1, from the semiconductor die 110 over the channel Ch2 to the semiconductor die 120.

At operation 614, an input signal and an input clock signal associated with the input signal are received from the semiconductor die, wherein the input signal corresponds to the output signal, and the input clock signal corresponding to the output clock signal. For example, as described with respect to FIG. 3, the input signal comprises signal D1 received by the semiconductor die 120, turned around through the electrical connection 320, and sent back over the channel Ch3 to be received by the semiconductor die 110 as the signal D5. The input clock signal comprises the clock signal Clk_out1 received by the semiconductor die 120, and then returned, through the multiplexer MUX2 having the selection signal Sel2 being logic “0”, over the channel Ch4, back to the semiconductor die 110.

At operation 616, based on a comparison of data in the output signal with data obtained from the input signal, a clock signal is selected. For example, as described with respect to FIG. 3, the data in the output signal, i.e., the signal D1, comprise one or more predetermined, or known, original test patterns. The data in the output signal comprise returned test patterns which are the original test patterns in the signal D1 passing through the back and forth communications between the semiconductor die 110 and semiconductor die 120 as described at operations 612, 614. If the returned test patterns match, e.g., are identical to, the original test pattern, a clock signal, e.g., the clock signal CLK5, used for reading out the returned test patterns is properly configured, and is selected for further communications. Otherwise, another configuration of the clock signal CLK5 is selected. In the example configuration in FIG. 3, alternative configurations of the clock signal CLK5 comprise the clock signal CLK1 corresponding to the selection signal Sel1 being logic “1”, and the inverted clock signal CLK1 corresponding to the selection signal Sel1 being logic “0”. In at least one embodiment, the selection of the clock signal for reading out the returned test pattern comprises a selection of a corresponding value, e.g., logic “0” or logic “1”, of the selection signal Sel1.

At operation 618, based on the selected clock signal, further data from further input signals are received from the semiconductor die. For example, as described with respect to FIGS. 1 and 3, with a specific value of the selection signal Sel1 being selected at operation 616, the corresponding configuration of the clock signal CLK5 is also selected at the flip-flop FF5, and further data in further input signals (other than test signals or returned test signals) are read out, e.g., in a normal operation (other than a calibration process) between the semiconductor die 110 and semiconductor die 120.

In at least one embodiment, the selected value of the selection signal Sel1 at operation 616 is stored in a storage circuit. In some embodiments, the described calibration process comprising operations 612, 614, 616 is repeated, as schematically indicated by arrow 620, one demand and/or periodically. One or more advantages described herein are achievable by the method 600A, in accordance with some embodiments.

FIG. 6B is a flow chart of a method 600B, in accordance with some embodiments. In some embodiments, the method 600B is performed at an IC device corresponding to one or more of the IC devices described with respect to FIGS. 4A-4D, 5B. The method 600B comprises operations 632, 634, 636.

At operation 632, an input signal and an input clock signal associated with the input signal are received from a semiconductor die. For example, in FIG. 4A, as seen from the semiconductor die 120, an input signal received from the semiconductor die 110 comprises the signal D2, and an input clock signal associated with the signal D2 and received from the semiconductor die 110 comprises the clock signal Clk_out1.

At operation 634, based on the input clock signal, an output clock signal having a phase lead relative to the input clock signal is generated. For example, in FIG. 4A, as seen from the semiconductor die 120, an output clock signal comprises the clock signal Clk_in2. As described with respect to FIGS. 4A, 4B, the clock signal Clk_in2 is generated based on the clock signal Clk_out1, and has a phase lead 430 relative to the clock signal Clk_out1.

At operation 636, (i) an output signal based on the output clock signal and (ii) the output clock signal are transmitted to the semiconductor die. For example, as described with respect to FIG. 4A, the output signal comprises the signal D3 sent, based on the clock signal Clk_in2 supplied as the clock signal CLK3 to the flip-flop FF3, over the channel Ch3 to the semiconductor die 110. The clock signal Clk_in2 is also sent, over the channel Ch4, to the semiconductor die 110. One or more advantages described herein are achievable by the method 600B, in accordance with some embodiments.

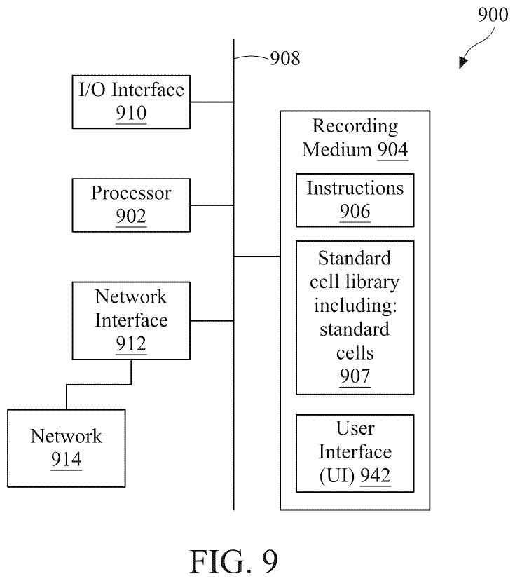

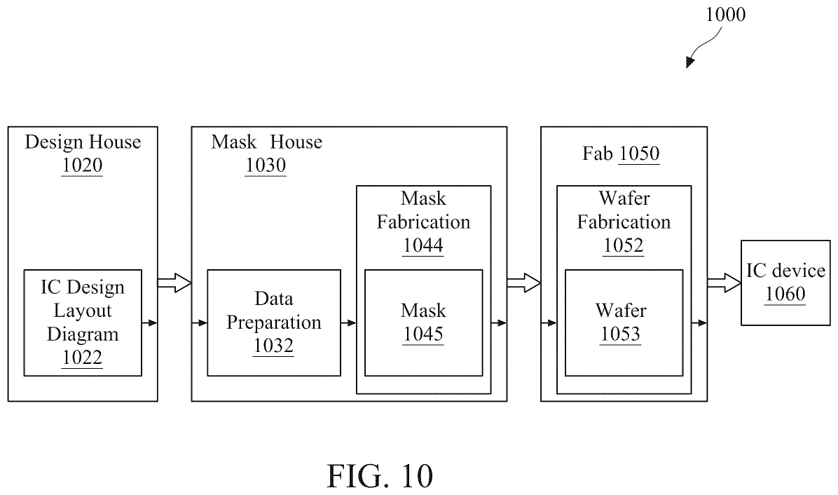

FIG. 6C is a flow chart of a method 600C, in accordance with some embodiments. In some embodiments, the method 600C is performed at a designing stage for designing an IC device corresponding to one or more of the IC devices described with respect to FIGS. 4A-4D, 5C. In some embodiments, the method 600C is performed in whole or in part by a processor and/or by at least one EDA system as described herein with respect to FIG. 9. In some embodiments, an EDA system is usable as part of a design house of an IC manufacturing system as described with respect to FIG. 10. The method 600C comprises operations 652, 654, 656, 658.

At operation 652, a first time delay is determined between (i) a master clock signal of a first semiconductor die and (ii) an output clock signal corresponding to the master clock signal received by a clock input buffer of a second semiconductor die. For example, as described with respect to FIG. 4A, a first time delay td1 is determined between a master clock signal, e.g., clock signal Clk_in1, of a first semiconductor die 110, and an output clock signal, e.g., clock signal Clk_out1. The clock signal Clk_out1 corresponds to the master clock signal received by a clock input buffer Rx2 of a second semiconductor die 120. The time delay td1 occurs over a first path comprising various circuit elements, e.g., the clock driver 115, the clock output buffer Tx2, the D2D interface structure configuring the channel Ch2, and the clock input buffer Rx2.

At operation 654, a second time delay is determined between (a) a returned clock signal, the returned clock signal corresponding to the output clock signal and sent by a clock output buffer of the second semiconductor die to the first semiconductor die, and (b) an input clock signal corresponding to the returned clock signal received at the first semiconductor die. For example, as described with respect to FIG. 4A, a second time delay td2 is determined between a returned clock signal, e.g., clock signal Clk_in2, and an input clock signal, e.g., the clock signal Clk_out2. The clock signal Clk_in2 corresponds to the clock signal Clk_out1, and is sent by a clock output buffer Tx4 of the semiconductor die 120 to the semiconductor die 110. The clock signal Clk_out2 corresponds to the clock signal Clk_in2 received at the semiconductor die 110. The time delay td2 occurs over a second path comprising various circuit elements, e.g., the clock driver 125, the clock output buffer Tx4, the D2D interface structure configuring the channel Ch4, the clock input buffer Rx4.

In at least one embodiment, based on various physical and/or electrical characteristics of the circuit elements in the first path and second path, it is possible to determine the time delay td1 and time delay td2. In some embodiments, the physical and/or electrical characteristics of the circuit elements are obtained from one or more of standard cells constituting the circuit elements, configurations of conductors routed to couple the standard cells, configurations of D2D interface structures to be formed for coupling the semiconductor die 110 and semiconductor die 120, one or more simulations of operations of the IC device 100, or the like. In some embodiments, operation 654 is performed before, or at least partially concurrently with, operation 652. In at least one embodiment, when the configurations of the first path and the second path are the same or substantially the same, i.e., td1 is the same or substantially the same as td2, one of the operations 652, 654 is omitted.

At operation 656, based on the first time delay and the second time delay, a time delay of a delay circuit is configured, wherein the delay circuit is in a feedback path of a phase-locked loop (PLL) coupled between the clock input buffer and the clock output buffer of the second semiconductor die. For example, as described with respect to FIG. 4A, based on a sum of td1+td2, a time delay t_match of the delay circuit 425 in the feedback path 424 of the PLL 420 is configured. The PLL 420 is coupled between the clock input buffer Rx2 and the clock output buffer Tx4 of the semiconductor die 120. In at least one embodiment, the time delay t_match is configured to be equal, or as close as possible, to td1+td2. The delay circuit 425 comprises circuit elements 426 each of which, in turn, is built from one or more standard cells, e.g., delay cells, buffer cells, inverter cells, or the like. In at least one embodiment, based on predetermined or known time delays of the standard cells constituting the circuit elements 426, a combination of standard cells forming the delay circuit 425 is generated to provide the time delay t_match be equal, or as close as possible, to td1+td2. In some embodiments, one or more simulations are executed for generating or adjusting the combination of standard cells forming the delay circuit 425. In some embodiments, a resulting design of the IC device 100 obtained at operation 656 is in a form of a layout stored in a non-transitory computer-readable recording medium.

At operation 658, an IC device is fabricated to comprise the first semiconductor die and the second semiconductor die bonded and electrically coupled to each other. For example, the stored layout is used in an IC manufacturing system, described with respect to FIG. 10, to fabricate the semiconductor die 110 and semiconductor die 120. In some embodiments, the semiconductor die 110 and semiconductor die 120 are bonded and electrically coupled together in one or more configurations described herein, e.g., with respect to FIGS. 8A-8B. In some embodiments, operation 656 is omitted. One or more advantages described herein are achievable by IC devices designed and/or fabricated by the method 600C, in accordance with some embodiments.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

FIG. 7 is a schematic diagram of a clock distribution system 700 for an IC device, in accordance with some embodiments. In at least one embodiment, the clock distribution system 700 is provided on a semiconductor die of the IC device.

The clock distribution system 700 is configured to receive a clock signal 704 from a clock source 702, and to distribute the clock signal 704 to various circuitry in the IC device. The clock distribution system 700 comprises a plurality of clock drivers 710-719 arranged at various locations in the clock distribution system 700, a pre-mesh clock tree 720, a clock mesh structure 730, and a plurality of post-mesh clock trees 741-744. A plurality of clock loads or clock sinks 751-755 are electrically coupled to the clock distribution system 700 to receive clock signals distributed therefrom.

In some embodiments, the clock source 702 comprises one or more of an oscillator circuit, a phase-locked loop (PLL), a clock divider circuit, or the like. Other clock source configurations are within the scopes of various embodiments. In at least one embodiment, the clock source 702 is an internal clock source included in the IC device that comprises the clock distribution system 700. In at least one embodiment, the clock source 702 is an external clock source arranged outside the IC device, and is electrically coupled to the IC device, e.g., via one or more input/output (IO) pins of the IC device. Other configurations of the clock source 702 are within the scopes of various embodiments.

In some embodiments, each of the clock drivers 710-719 comprises one or more of a buffer, an inverter, an amplifier, a logic gate, or the like. Other clock driver configurations are within the scopes of various embodiments. The arrangement of the clock drivers 710-719 in the clock distribution system 700 as illustrated in FIG. 7 is an example. Other configurations are within the scopes of various embodiments. For example, one or more of the clock drivers 710-719 is/are omitted and/or one or more further clock drivers is/are added, in accordance with some embodiments.

In the example configuration in FIG. 7, the pre-mesh clock tree 720 comprises an upper tier 721 and a lower tier 722. The upper tier 721 comprises a metal pattern sometimes referred to as a trunk of the pre-mesh clock tree 720, and is electrically coupled to an output of the clock driver 710. The clock driver 710 further has an input electrically coupled to the clock source 702 to receive the clock signal 704, and is configured to deliver the clock signal 704 to the pre-mesh clock tree 720. Opposite ends of the metal pattern of the upper tier 721 are electrically coupled to inputs of the clock drivers 711-712. The lower tier 722 comprises metal patterns 723, 724 which are sometimes referred to as branches of the pre-mesh clock tree 720, and are electrically coupled correspondingly to outputs of the clock drivers 711-712. Opposite ends of the metal pattern 723 are electrically coupled to inputs of the clock drivers 713-714. Opposite ends of the metal pattern 724 are electrically coupled to inputs of the clock drivers 715-716. The example configuration of the pre-mesh clock tree 720 in FIG. 7 is an H-tree. Other clock tree configurations are within the scopes of various embodiments, as described herein. For example, in one or more embodiments, the clock mesh structure 730 comprises one tier, or more than two tiers. In at least one embodiment, the pre-mesh clock tree 720 is omitted.

The clock mesh structure 730 is electrically coupled to outputs of the clock drivers 713-716. The clock mesh structure 730 comprises a plurality of metal patterns arranged in one or more metal layers and all electrically coupled to each other to short the outputs of the clock drivers 713-716. As a result, the same clock signal, or substantially the same clock signal, is retrievable at any point on the clock mesh structure 730. The clock mesh structure 730 comprises a plurality of tap points from which the clock signal is obtained to be delivered to clock loads in the circuitry of the IC device. In the example configuration in FIG. 7, five tap points 731-735 are indicated for illustrative purposes. An actual number and/or location of tap points on the clock mesh structure 730 depend on how clock loads are distributed in the circuit of the IC device. The configuration of the clock mesh structure 730 with two sets of parallel wirings in FIG. 7 is an example, and is sometimes referred to as the “Manhattan” configuration. Other clock mesh structure configurations are within the scopes of various embodiments. In at least one embodiment, the clock mesh structure 730 is omitted.

The post-mesh clock trees 741-744 are electrically coupled to the clock mesh structure 730 at the corresponding tap points 731-734. The post-mesh clock trees 741-743 are electrically coupled to the corresponding tap points 731-733 through the corresponding clock drivers 717-719, and are configured to deliver the clock signal to corresponding clock loads 751-753. The post-mesh clock tree 744 is electrically coupled to the corresponding tap point 744 directly without a clock driver in between, and is configured to deliver the clock signal to corresponding clock load 754. A clock load 755 is electrically coupled to the tap point 735 directly, without a clock driver or a post-mesh clock tree in between. In some embodiments, each of the clock loads 751-755 comprises a flip-flop, or the like.

Other clock load configurations are within the scopes of various embodiments. In at least one embodiment, one or more or all of the post-mesh clock trees 741-743 is/are omitted.

The configuration of the clock distribution system 700 in FIG. 7 is an example. Other clock distribution system configurations are within the scopes of various embodiments. For example, in one or more embodiments, the pre-mesh clock tree 720 is omitted and the output of the clock driver 710 is electrically coupled to a center point 737 of the clock mesh structure 730. In at least one embodiment, the clock mesh structure 730 is omitted and at least one metal pattern of the pre-mesh clock tree 720 is configured as a clock spine to which the clock loads are electrically coupled. In one or more embodiments, the clock distribution system 700 comprises one or more of the clock trees 720, 741-744, and has no clock mesh structure.

FIG. 8A is schematic diagram of an IC device 800A, in accordance with some embodiments.

The IC device 800A is a 3D IC and comprises semiconductor dies 810, 820 stacked along a Z axis on, and coupled to, an interposer 830. The semiconductor die 810 comprises a plurality of I/O circuits 814 coupled and bonded by bumps 816 to corresponding interconnects 836 in the interposer 830. The semiconductor die 820 comprises a plurality of I/O circuits 824 coupled and bonded by bumps 826 to corresponding interconnects 836 in the interposer 830, to be thereby coupled to the corresponding I/O circuits 814 of the semiconductor die 810. As a result, the semiconductor die 810 is coupled by the bumps 816, 826 and the interposer 830 to the semiconductor die 820. In some embodiments, each I/O circuit 814, 816 comprises a data I/O circuit or a clock I/O circuit.

In some embodiments, the IC device 800A corresponds to one or more IC devices described with respect to FIGS. 1A-5B, and/or the semiconductor die 810 corresponds to one or more of the semiconductor dies 110, 510, and/or the semiconductor die 820 corresponds to one or more of the semiconductor dies 120, 520, 521. In at least one embodiment, a combination each bump 816, the corresponding interconnect 836 and the corresponding bump 826 corresponds to one interface structure 130 or one interface structure 530.

FIG. 8B is schematic diagram of an IC device 800B, in accordance with some embodiments. Components in FIG. 8B having corresponding components in FIG. 8A are designated by the same reference numerals as in FIG. 8A.

In the IC device 800B, the interposer 830 of the IC device 800A is omitted. The semiconductor die 810 and the semiconductor die 820 are bonded and electrically coupled to each other in a face-to-face configuration. For example, each bump 816 of the semiconductor die 810 is over and bonded to a corresponding bump 826 of the semiconductor die 820. The combination each bump 816 and the corresponding bump 826 corresponds to one interface structure 130 or one interface structure 530. One or more advantages described herein are achievable by one or more of the IC devices 800A, 800B, in accordance with some embodiments. The described 3D IC configurations in FIGS. 8A, 8B are examples. Other 3D IC configurations are within the scopes of various embodiments.

FIG. 9 is a block diagram of an electronic design automation (EDA) system 900 in accordance with some embodiments.

In some embodiments, EDA system 900 includes an APR system. Methods described herein of designing layout diagrams represent wire routing arrangements, in accordance with one or more embodiments, are implementable, for example, using EDA system 900, in accordance with some embodiments.

In some embodiments, EDA system 900 is a general purpose computing device including a hardware processor 902 and a non-transitory, computer-readable recording medium 904. Recording medium 904, amongst other things, is encoded with, i.e., stores, computer program code 906, i.e., a set of executable instructions. Execution of instructions 906 by hardware processor 902 represents (at least in part) an EDA tool which implements a portion or all of the methods described herein in accordance with one or more embodiments (hereinafter, the noted processes and/or methods).

Processor 902 is electrically coupled to computer-readable recording medium 904 via a bus 908. Processor 902 is also electrically coupled to an I/O interface 910 by bus 908. A network interface 912 is also electrically connected to processor 902 via bus 908. Network interface 912 is connected to a network 914, so that processor 902 and computer-readable recording medium 904 are capable of connecting to external elements via network 914. Processor 902 is configured to execute computer program code 906 encoded in computer-readable recording medium 904 in order to cause system 900 to be usable for performing a portion or all of the noted processes and/or methods. In one or more embodiments, processor 902 is a central processing unit (CPU), a multi-processor, a distributed processing system, an application specific integrated circuit (ASIC), and/or a suitable processing unit.

In one or more embodiments, computer-readable recording medium 904 is an electronic, magnetic, optical, electromagnetic, infrared, and/or a semiconductor system (or apparatus or device). For example, computer-readable recording medium 904 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 904 includes a compact disk-read only memory (CD-ROM), a compact disk-read/write (CD-R/W), and/or a digital video disc (DVD).

In one or more embodiments, recording medium 904 stores computer program code 906 configured to cause system 900 (where such execution represents (at least in part) the EDA tool) to be usable for performing a portion or all of the noted processes and/or methods. In one or more embodiments, recording medium 904 also stores information which facilitates performing a portion or all of the noted processes and/or methods. In one or more embodiments, recording medium 904 stores library 907 of standard cells including such standard cells as disclosed herein.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 902.

EDA system 900 also includes network interface 912 coupled to processor 902. Network interface 912 allows system 900 to communicate with network 914, to which one or more other computer systems are connected. Network interface 912 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

System 900 is configured to receive information through I/O interface 910. The information received through I/O interface 910 includes one or more of instructions, data, design rules, libraries of standard cells, and/or other parameters for processing by processor 902. The information is transferred to processor 902 via bus 908. EDA system 900 is configured to receive information related to a user interface (UI) through I/O interface 910. The information is stored in computer-readable recording medium 904 as UI 942.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 10 is a block diagram of an integrated circuit (IC) manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1000.

In FIG. 10, IC manufacturing system 1000 includes entities, such as a design house 1020, a mask house 1030, and an IC manufacturer/fabricator (“fab”) 1050, that interact with one another in the design, development, and manufacturing cycles and/or services related to manufacturing an IC device 1060. The entities in system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1020, mask house 1030, and IC fab 1050 is owned by a single larger company. In some embodiments, two or more of design house 1020, mask house 1030, and IC fab 1050 coexist in a common facility and use common resources.

Design house (or design team) 1020 generates an IC design layout diagram 1022. IC design layout diagram 1022 includes various geometrical patterns designed for an IC device 1060. The geometrical patterns correspond to patterns of metal, oxide, or semiconductor layers that make up the various components of IC device 1060 to be fabricated. The various layers combine to form various IC features. For example, a portion of IC design layout diagram 1022 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1020 implements a proper design procedure to form IC design layout diagram 1022. The design procedure includes one or more of logic design, physical design or place-and-route operation. IC design layout diagram 1022 is presented in one or more data files having information of the geometrical patterns. For example, IC design layout diagram 1022 can be expressed in a GDSII file format or DFII file format.

Mask house 1030 includes data preparation 1032 and mask fabrication 1044. Mask house 1030 uses IC design layout diagram 1022 to manufacture one or more masks 1045 to be used for fabricating the various layers of IC device 1060 according to IC design layout diagram 1022. Mask house 1030 performs mask data preparation 1032, where IC design layout diagram 1022 is translated into a representative data file (“RDF”). Mask data preparation 1032 provides the RDF to mask fabrication 1044. Mask fabrication 1044 includes a mask writer. A mask writer converts the RDF to an image on a substrate, such as a mask (reticle) 1045 or a semiconductor wafer 1053. The design layout diagram 1022 is manipulated by mask data preparation 1032 to comply with particular characteristics of the mask writer and/or requirements of IC fab 1050. In FIG. 10, mask data preparation 1032 and mask fabrication 1044 are illustrated as separate elements. In some embodiments, mask data preparation 1032 and mask fabrication 1044 can be collectively referred to as mask data preparation.

In some embodiments, mask data preparation 1032 includes optical proximity correction (OPC) which uses lithography enhancement techniques to compensate for image errors, such as those that can arise from diffraction, interference, other process effects and the like. OPC adjusts IC design layout diagram 1022. In some embodiments, mask data preparation 1032 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1032 includes a mask rule checker (MRC) that checks the IC design layout diagram 1022 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1022 to compensate for limitations during mask fabrication 1044, which may undo part of the modifications performed by OPC in order to meet mask creation rules.

In some embodiments, mask data preparation 1032 includes lithography process checking (LPC) that simulates processing that will be implemented by IC fab 1050 to fabricate IC device 1060. LPC simulates this processing based on IC design layout diagram 1022 to create a simulated manufactured device, such as IC device 1060. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1022.

It should be understood that the above description of mask data preparation 1032 has been simplified for the purposes of clarity. In some embodiments, data preparation 1032 includes additional features such as a logic operation (LOP) to modify the IC design layout diagram 1022 according to manufacturing rules. Additionally, the processes applied to IC design layout diagram 1022 during data preparation 1032 may be executed in a variety of different orders.

After mask data preparation 1032 and during mask fabrication 1044, a mask 1045 or a group of masks 1045 are fabricated based on the modified IC design layout diagram 1022. In some embodiments, mask fabrication 1044 includes performing one or more lithographic exposures based on IC design layout diagram 1022. In some embodiments, an electron-beam (e-beam) or a mechanism of multiple e-beams is used to form a pattern on a mask (photomask or reticle) 1045 based on the modified IC design layout diagram 1022. Mask 1045 can be formed in various technologies. In some embodiments, mask 1045 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1045 includes a transparent substrate (e.g., fused quartz) and an opaque material (e.g., chromium) coated in the opaque regions of the binary mask. In another example, mask 1045 is formed using a phase shift technology. In a phase shift mask (PSM) version of mask 1045, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1044 is used in a variety of processes. For example, such a mask(s) is used in an ion implantation process to form various doped regions in semiconductor wafer 1053, in an etching process to form various etching regions in semiconductor wafer 1053, and/or in other suitable processes.

IC fab 1050 is an IC fabrication business that includes one or more manufacturing facilities for the fabrication of a variety of different IC products. In some embodiments, IC Fab 1050 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1050 includes fabrication tools 1052 configured to execute various manufacturing operations on semiconductor wafer 1053 such that IC device 1060 is fabricated in accordance with the mask(s), e.g., mask 1045. In various embodiments, fabrication tools 1052 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1050 uses mask(s) 1045 fabricated by mask house 1030 to fabricate IC device 1060. Thus, IC fab 1050 at least indirectly uses IC design layout diagram 1022 to fabricate IC device 1060. In some embodiments, semiconductor wafer 1053 is fabricated by IC fab 1050 using mask(s) 1045 to form IC device 1060. In some embodiments, the IC fabrication includes performing one or more lithographic exposures based at least indirectly on IC design layout diagram 1022. Semiconductor wafer 1053 includes a silicon substrate or other proper substrate having material layers formed thereon. Semiconductor wafer 1053 further includes one or more of various doped regions, dielectric features, multilevel interconnects, and the like (formed at subsequent manufacturing steps).

In some embodiments, an integrated circuit (IC) device comprises a first semiconductor die which comprises a first transmitting circuit, a first receiving circuit, and a first circuit. The first transmitting circuit is configured to transmit an output clock signal corresponding to a first clock signal. The first receiving circuit is configured to receive an input clock signal and an input signal, and output, based on the input clock signal, a first signal corresponding to the input signal. The first circuit is configured to output, based on the first clock signal, a second signal corresponding to the first signal. The first circuit is configured to, in response to a first value of a first selection signal, output the second signal in response to a first edge of the first clock signal. The first circuit is further configured to, in response to a second value of the first selection signal, output the second signal in response to a second edge of the first clock signal. The second value is different from the first value.

In some embodiments, an integrated circuit (IC) device comprises a clock input buffer, a clock management circuit, a controllable switch, and a clock output buffer. The clock input buffer comprises an input configured to be coupled to a die-to-die (D2D) interface structure to receive an input clock signal, and an output. The clock management circuit comprises an input coupled to the output of the clock input buffer to receive the input clock signal from the clock input buffer, and an output. The clock management circuit is configured to generate and output a further clock signal corresponding to the input clock signal. The controllable switch comprises a first input coupled to the output of the clock input buffer to receive the input clock signal, a second input coupled the output of the clock management circuit to receive the further clock signal, and an output. The clock output buffer comprises an input coupled to the output of the controllable switch, which is configured to controllably output one of the input clock signal and the further clock signal, and an output configured to be coupled to a further D2D interface structure to transmit an output clock signal corresponding to the one of the input clock signal and the further clock signal output by the controllable switch.

In some embodiments, a method comprises receiving, from a semiconductor die, an input signal and an input clock signal associated with the input signal. The method further comprises generating, based on the input clock signal, an output clock signal having a phase lead relative to the input clock signal. The method further comprises transmitting, to the semiconductor die, (i) an output signal based on the output clock signal, and (ii) the output clock signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first semiconductor die, comprising:
a first transmitting circuit configured to transmit an output clock signal corresponding to a first clock signal;
a first receiving circuit configured to
receive an input clock signal and an input signal, and
output, based on the input clock signal, a first signal corresponding to the input signal; and
a first circuit configured to output, based on the first clock signal, a second signal corresponding to the first signal,
wherein the first circuit is configured to
in response to a first value of a selection signal, output the second signal in response to a first edge of the first clock signal, and
in response to a second value of the selection signal, output the second signal in response to a second edge of the first clock signal, and
the second value is different from the first value.

2. The IC device of claim 1, wherein
the first transmitting circuit is further configured to transmit, based on the first clock signal, an output signal, and
the input signal is responsive to the output signal.

3. The IC device of claim 1, wherein
the first edge is one of a rising edge and a falling edge of the first clock signal, and
the second edge is the other of the rising edge and the falling edge of the first clock signal.

4. The IC device of claim 1, wherein
the first edge is half a clock cycle away from the second edge.

5. The IC device of claim 1, wherein the first circuit comprises:
a flip-flop, comprising:
an input coupled to the first receiving circuit to receive the first signal,
an output at which the flip-flop is configured to output the second signal, and
a clock input, and
a multiplexer, comprising:
a non-inverting input configured to receive the first clock signal,
an inverting input configured to receive the first clock signal,
a selection input configured to receive the selection signal, and
an output coupled to the clock input of the flip-flop.

6. The IC device of claim 5, wherein
the selection signal has the first value, and
the flip-flop has setup time t_setup_ta and a hold time t_hold_ta satisfying following relationships:
t_setup_a=T/2+t_mux−t_x, and
t_hold_a=t_x+T/2−t_mux,
where
T is a clock cycle of the output clock signal,
t_mux is a time delay of the multiplexer, and
t_x is a time delay between the output clock signal and the first signal.

7. The IC device of claim 5, wherein
the selection signal has the second value, and
the flip-flop has setup time t_setup_tb and a hold time t_hold_tb satisfying following relationships:
t_setup_b=T+t_mux−t_x, and
t_hold_b=t_x−t_mux,
where
T is a clock cycle of the output clock signal,
t_mux is a time delay of the multiplexer, and
t_x is a time delay between the output clock signal and the first signal.

8. The IC device of claim 5, wherein
the first circuit further comprises a storage circuit having an output coupled to the selection input of the multiplexer, and
the storage circuit storing a predetermined value of the selection signal, the predetermined value corresponding to either
the multiplexer configured to output the first clock signal received at the non-inverting input to the clock input of the flip-flop, or
the multiplexer configured to output the first clock signal received at the inverting input to the clock input of the flip-flop.

9. The IC device of claim 1, wherein
the first transmitting circuit is further configured to transmit, based on the first clock signal, an output signal corresponding to a test signal,
the input signal corresponds to the output signal, and
the first semiconductor die further comprises a control circuit configured to generate the selection signal to
select one edge of a rising edge and a falling edge of the first clock signal, based on a comparison of first data in the test signal and second data in the second signal, and
control the first circuit to output the second signal in response to the selected edge of the first clock signal.

10. The IC device of claim 9, wherein the first circuit comprises:
a flip-flop, comprising:
an input coupled to the first receiving circuit to receive the first signal,
an output at which the flip-flop is configured to output the second signal, and
a clock input, and
a multiplexer, comprising:
a non-inverting input configured to receive the first clock signal,
an inverting input configured to receive the first clock signal,
a selection input coupled to an output of the control circuit to receive the selection signal corresponding to the selected edge, and
an output coupled to the clock input of the flip-flop.

11. The IC device of claim 1, wherein
the first value of the selection signal corresponds to a first relationship between (i) one half of a clock cycle of the output clock signal and (ii) a time delay between the output clock signal and the first signal, and
the second value of the selection signal corresponds to a second relationship between (i) the one half of the clock cycle of the output clock signal and (ii) the time delay between the output clock signal and the first signal, the second relationship different from the first relationship.

12. The IC device of claim 1, further comprising:
a second semiconductor die, comprising:
a second receiving circuit coupled to the first transmitting circuit to receive the output clock signal; and
a second transmitting circuit coupled to the first receiving circuit, and configured to
transmit, based on the output clock signal, the input signal to the first receiving circuit, and
transmit the input clock signal corresponding to the output clock signal to the first receiving circuit.

13. The IC device of claim 12, wherein
the second semiconductor die further comprises a multiplexer, the multiplexer comprising:
a first input configured to receive the output clock signal,
a second input configured to receive to a second clock signal of the second semiconductor die, the second clock signal independent from the first clock signal of the first semiconductor die or having a phase lead relative to the output clock signal,
a selection input configured to receive a further selection signal, and
an output coupled to the second transmitting circuit, and
the multiplexer is configured to, responsive to the further selection signal, output one of the second clock signal or the received output clock signal to the second transmitting circuit.

14. An integrated circuit (IC) device, comprising:
a clock input buffer, comprising:
an input configured to be coupled to a die-to-die (D2D) interface structure to receive an input clock signal, and
an output;
a clock management circuit, comprising:
an input coupled to the output of the clock input buffer to receive the input clock signal from the clock input buffer, and
an output, wherein the clock management circuit is configured to generate and output a further clock signal corresponding to the input clock signal;
a controllable switch, comprising:
a first input coupled to the output of the clock input buffer to receive the input clock signal,
a second input coupled the output of the clock management circuit to receive the further clock signal, and
an output; and
a clock output buffer, comprising:
an input coupled to the output of the controllable switch, which is configured to controllably output one of the input clock signal and the further clock signal, and
an output configured to be coupled to a further D2D interface structure to transmit an output clock signal corresponding to the one of the input clock signal and the further clock signal output by the controllable switch.

15. The IC device of claim 14, wherein at least one of:
the clock management circuit comprises a phase locked loop (PLL) with a feedback path, or
the controllable switch comprises a multiplexer.

16. The IC device of claim 14, wherein
the clock management circuit comprises:
a phase locked loop (PLL) with a feedback path, and
a clock tree and a delay circuit in the feedback path.

17. A method, comprising:
receiving, from a semiconductor die, an input signal and an input clock signal associated with the input signal;
generating, based on the input clock signal, an output clock signal having a phase lead relative to the input clock signal; and
transmitting, to the semiconductor die, (i) an output signal based on the output clock signal, and (ii) the output clock signal.

18. The method of claim 17, wherein
said generating the output clock signal comprises:
supplying the input clock signal to a reference input of a phase locked loop (PLL), and
obtaining the output clock signal from an output of the PLL,
wherein the PLL comprises a feedback path coupled between a feedback input of the PLL and the output of the PLL.

19. The method of claim 18, wherein
said generating the output clock signal further comprises:
causing a time delay in the feedback path of the PLL.

20. The method of claim 19, wherein
the time delay corresponds to a sum of
a first time delay of a first signal path over which the input clock signal is received from the semiconductor die, and
a second time delay of a second signal path over which the output clock signal is transmitted to the semiconductor die.
